(19) United States
(12) Patent Application Publication
(10) Pub. No.: US 2015/0333242 A1
(43) Pub. Date: Nov. 19, 2015

(54) Energy Generation Device Using Non-Maxwellian Gases

(71) Applicant: George Samuel Levy, San Diego, CA (US)

(72) Inventor: George Samuel Levy, San Diego, CA (US)

(21) Appl. No.: 14/788,707

(22) Filed: Jun. 30, 2015

Related U.S. Application Data
(63) Continuation-in-part of application No. 13/668,914, filed on Nov. 5, 2012.
(60) Provisional application No. 61/558,603, filed on Nov. 11, 2011.
(60) Provisional application No. 61/567,455, filed on Dec. 6, 2011.
(60) Provisional application No. 61/583,185, filed on Jan. 5, 2012.
(60) Provisional application No. 61/594,354, filed on Feb. 2, 2012.
(60) Provisional application No. 61/610,315, filed on Mar. 13, 2012.
(60) Provisional application No. 62/151,387, filed on Apr. 22, 2015.
(60) Provisional application No. 62/108,048, filed on Jan. 26, 2015.
(60) Provisional application No. 62/069,108, filed on Oct. 27, 2014.

(51) Int. Cl. H01L 35/00

(52) U.S. Cl. CPC H01L 35/00

(57) ABSTRACT

An energy generator using a potential energy gradient applied to a non-Maxwellian gas occupying and restricted to a volume, to generate a temperature difference between regions in this volume. This temperature difference occurs in the absence of any flow of particles in or out of this volume. The volume can be embodied by a semiconductor and particles, by electrons or holes in the semiconductor. Electrical power can be generated from the temperature difference by connecting a Seebeck device across it or by using the temperature difference to drive an electrical analog of the fixed-vane Crookes radiometer to propel electrical carriers. When two such Crookes radiometers are formed across a junction, electrons and holes can be driven toward each other in the absence of any external voltage source, thereby producing electromagnetic radiation. Applications include heating, cooling, electrical energy production and lighting.

### PRIORITY

This application is a continuation-in-part of U.S. Non-provisional application Ser. No. 13/668,914 titled Energy Generation Device filed on Nov. 5, 2012 which, pursuant to 35 U.S.C. Par 119(e)(i), claims priority benefit of:
U.S. provisional application No. 61/558,603 titled “Energy Generation Engine” filed on Nov. 11, 2011;
U.S. provisional application No. 61/567,455 titled “Energy Generation Engine” filed on Dec. 6, 2011;
U.S. provisional application No. 61/583,185 titled “Energy Generation Engine” filed on Jan. 5, 2012;
U.S. provisional application No. 61/594,354 titled “Energy Generation Engine” filed on Feb. 2, 2012;
U.S. provisional application No. 61/610,315 titled “Energy Generation Engine” filed on Mar. 13, 2012;
   the aforesaid patent applications have been incorporated by reference.

In addition, this application claims priority benefit pursuant to 35 U.S.C. Par 119(e)(i) of U.S. provisional application No. 62/151,387 titled “Energy Generation Device Using Non-Maxwellian Gases” filed on Apr. 22, 2015; the aforesaid patent applications have been incorporated by reference.

### ADDITIONAL INCORPORATION BY REFERENCE

The following patents and applications are also incorporated by reference.
U.S. Pat. No. 5,550,387 by Elsner et al “Superlattice Quantum Well Material”
U.S. Pat. No. 5,856,210 by Leavitt et al, “Method of fabricating a thermoelectric module with gapless eggcrate.
U.S. Pat. No. 5,875,098 by Leavitt et al., “Thermoelectric Module with Gapless Eggcrate”
U.S. Pat. No. 6,096,964 by Ghamaty et al, “Quantum Well Thermoelectric Material on Thin Flexible Substrate.”
U.S. Pat. No. 6,096,965 by Ghamaty et al. “Quantum Well Thermoelectric Material on Organic Substrate.”
U.S. Pat. No. 6,828,579 by Ghamaty et al. “Thermoelectric Device with SI/SIC Superlattice N-Legs”.
U.S. Pat. No. 7,038,234 by Ghamaty et al. “Thermoelectric Module with SI/SIGE and B4C/B9C Super-Lattice Legs”.
U.S. Pat. No. 7,342,170 by Ghamaty et al. “Thermoelectric Module with SI/SIC and B4C/B9C Super-Lattice Legs”.
U.S. Pat. No. 7,400,050 by Jovanovic et al, “Quantum Well Thermoelectric Poser Source.”
US Patent Application 2008/0257395 by Jovanovic et al, “Miniature Quantum Well Thermoelectric device.”
US Patent Application 2010/0229911 by Leavitt et al, “High Temperature, High Efficiency Thermoelectric Module.”
US Patent Application 2011/0062420 by Ghamaty et al., Quantum Well Thermoelectric Module.”
US Patent Application 2008/0257395 by Jovanovic et al, “Miniature Quantum Well Thermoelectric device.”
US Patent Application 2011/0100408 by Kushch et al., “Quantum Well Module with Low K Crystalline Covered Substrates.”

### NON-PATENT LITERATURE INCORPORATED BY REFERENCE

Levy, G. “Thermoelectric Effects under Adiabatic Conditions” Entropy 2013, 15(11), 4700-4715 available at http://www.mdpi.com/1099-4300/15/11/4700#stats.
Levy, G. “Anomalous Temperature Gradient in Non-Maxwellian Gases,” ResearchGate, currently available at http://www.researchgate.net/publication/272621625_Anomalous_Temperature_Gradient_in_Non-Maxwellian_Gases. This paper has been presented to the 11th International Conference on Ceramic Materials and Components for Energy and Environmental Applications on Jun. 18, 2015 held in Vancouver Canada, and will be published after peer review in the conference proceedings.
Iwanaga, S.; Toberer, E. S.; LaLonde, A.; Snyder G. J. A high temperature apparatus for measurement of the Seebeck coefficient. Rev. Sci. Instrum. 2011, 82, 063905-1-063905-6.

### FIELD OF THE INVENTION

The present invention relates to engines in which a non-Maxwellian gas comprised of particles such as charge carriers in a semiconductor is subjected to a potential energy gradient and produces a temperature difference or a voltage difference in the absence of heat flow or current flow. This technology also relates to thermoelectric generators that use electrons or holes as thermal carriers and that operate according to the Seebeck effect or the Peltier effect.

### BACKGROUND

Conventional thermoelectric devices function according to three known effects:
1) The Peltier effect, in which a current I is used to force heat to move from one place to another. Using Peltier coefficient P, this effect is expressed as (from Wikipedia)

$$\frac{d Q}{d t} = PI , \qquad ( 1 )$$

2) The Seebeck effect, in which a temperature gradient ΔT produces a current density J assuming conductivity σ, voltage gradient ΔV and Seebeck coefficient S.

J=σ(−ΔV−SΔT), (2)
3) The Thomson effect, in which an electrical current density J passing through a temperature gradient ΔT produces a heat flow

$$\frac{d Q}{d t} .$$

$$\frac{d Q}{d t} = - KJ . ∇ T \qquad ( 3 )$$

The present invention describes a new thermoelectric effect as well as physical embodiments of this new effect, said embodiments having utility.

### SUMMARY OF THE INVENTION

This invention describes an energy generator that relies on a new thermoelectric effect in which a non-Maxwellian gas such as electrons confined to a volume and subjected to a potential energy gradient such as an electric field spontaneously develops a temperature gradient, without requiring the gas to flow. The result is that a cold region and a hot region form in the gas, with heat spontaneously flowing from the cold region to the hot region without any external power expenditure. This effect is markedly different from the Peltier effect which requires an input current to produce a temperature difference.

This phenomenon, not normally possible in a conventional Maxwellian gas governed by Classical Mechanics, becomes possible because it relies on the quantum mechanical properties of non-Maxwellian gases such as fermions—i.e., electrons or holes in semiconductor materials. More specifically, the phenomenon is due to the difference in the statistical properties of Maxwellian gases which are governed by the Maxwell-Boltzmann distribution and non-Maxwellian gases which are governed by other distributions such as the Fermi-Dirac distribution. Such non-Maxwellian gases can spontaneously a temperature difference when subjected to a potential energy gradient such as an electrical field. Fermions include electrons and holes in semiconductors.

However, other particles such as heat phonons, which are not affected by the potential energy gradient, tend to short circuit this gradient. It is therefore important to minimize the interaction between the carriers and the phonons. Ideally the carriers should behave ballistically with respect to the semiconductor lattice. This can be accomplished by selecting a material with a high ZT coefficient, in which the ratio of carrier thermal conductivity to phonon thermal conductivity is high.

It is also important for the particles of the non-Maxwellian gas to be capable of developing their own statistical distribution independently of the lattice. It is therefore also important for the carriers to interact between themselves for example through the mechanism of electron/electron scattering. The above requirements can be conflicting and the best approach is to find an acceptable compromise between them.

The existence of a potential energy gradient is also important. In a typical semiconductor junction, an electric field exists across the junction, that is, in the depletion region, but not in the bulk of the material because the field is quickly shielded by space charges that accumulate near the junction. If a junction is used to produce a potential energy gradient, then the active region, that is the location in the material that generates a temperature difference, is essentially the depletion region.

In the presence of an electric field, the potential energy gradient of electrons is opposite in direction to that of holes with the result that their kinetic energy and temperature gradients are also in opposite direction. The presence of both electrons and holes in a junction is therefore counterproductive in the generation of a temperature difference and the best approach toward this goal is to employ a unipolar junction with a single type of carriers. The unipolar junction then consists of a highly doped material with a lightly doped material, resulting in the carriers having a higher temperature at the highly doped region where their potential energy is the lowest and their kinetic energy is the highest.

The potential energy gradient can be also produced by an electric field generated externally by electrets or insulated electrodes on either side of a thermoelectric material. In this case, the region near the surface of the material operates as the depletion zone because the field is cancelled in the bulk of the material by space charges. Of course, since the bulk is not utilized, it can be dispensed of by fabricating the device with a thickness comparable to that of the depletion zone. When an external voltage is used to control the temperature difference, the device can be switched from a refrigerator to a heater simply by reversing the polarity of the voltage.

The potential energy gradient can also be produced when materials have different Fermi levels, which includes Schottky junctions and hetero-junctions.

The potential energy gradient can also be in the form of a phase change.

The techniques outlined above can be used to construct Temperature Difference Generators (TDGs) and these TDGs can be stacked to add up their outputs. Since the active region in a TDG is very thin (in the order of the depletion zone) the stacking can be in the form of a superlattice resulting in a compact device producing a significant temperature difference.

The TDGs described above can be thermally connected to Seebeck devices to produce electricity. Essentially the hot output of a TDG is connected to the hot input of a Seebeck device and the cold output of a TDG to the cold input of the Seebeck device.

Electrical power can be generated from the temperature difference by connecting a Seebeck device across a TDG or by using the temperature difference to drive an electrical analog of the fixed-vane Crookes radiometer embodied in a semiconductor to propel electrical carriers. To achieve such a Crookes radiometer analog, a semiconductor matrix is embedded with highly doped plates, one side of each plates being electrically insulated from the matrix and the other side of each plate being in electrical contact with the matrix. This configuration disrupts the thermal equilibrium (i.e. zero effective temperature difference) between the two faces of each plate, thereby generating a temperature difference between them. Asymmetrical orientation of the plates produces the fixed-vanes Crookes radiometer effect resulting in the propulsion of carriers along one preferred direction. To understand this effect one must understand that effective temperature and actual temperature are identical only when applied to Maxwellian gases. However, in non-Maxwellian gases heat flows down the effective temperature gradient, not the actual temperature gradient. A thermal short equalizes the actual temperatures but generates an effective temperature difference.

When two such Crookes radiometers are formed across a junction, the first radiometer propelling electrons and the second radiometer propelling holes, the electrons and holes can be driven toward each other in the absence of any external voltage source, thereby producing electromagnetic radiation such as light, infrared or microwaves, when the carriers annihilate.

A TDG could be as small as a molecule. For example, a polar molecule having a conduction band could embody such a device. An electron would have a higher potential energy and lower kinetic energy near the negative pole and, conversely, a lower potential energy and higher kinetic energy near the positive pole. This would result in more energetic modes of vibration, hence a higher temperature, near the positive pole than near the negative pole.

Applications of this technology include heating, cooling, electrical energy production and lighting. Power supplies and coolers can be fabricated as integral subcomponents of semiconductor chips or modules.

### BRIEF DESCRIPTION OF THE DRAWINGS

FIG. 1 illustrates the basic physical principle used by the embodiments in this invention. A Seebeck curve of voltage vs. temperature does not go through the origin because electrons or holes form a non-Maxwellian gas.

FIG. 2 shows the distribution of a Maxwellian gas at different elevation. The lower distribution at higher elevation indicates a decrease in the density of the particles.

FIG. 3 illustrates a particular property of exponential function. A shift along the horizontal axis corresponds to a change in gain or amplitude.

FIG. 4 shows that after renormalization a Maxwell distribution is invariant with elevation, indicating that the gas is isothermal.

FIG. 5 shows that an impulse distribution exemplified by a bouncing ball, is not isothermal with elevation.

FIG. 6 shows that the distribution of Fermions is the product of their density of states and their Fermi-Dirac distribution. The Fermion distribution changes with elevation because the Fermi-Dirac function shifts with elevation.

FIG. 7 shows that after renormalization, the distribution of Fermions is not invariant with elevation, indicating that the temperature of Fermions is not invariant with elevation. The same reasoning can be applied to Bosons.

FIG. 8 shows a possible embodiment of this invention capable of producing a temperature difference, hence called a temperature difference generator (TDG), comprising a layer of n type thermoelectric material inserted between two insulated capacitor plates.

FIG. 8A shows a possible embodiment of this invention comprising a layer of p type thermoelectric material inserted between two insulated capacitor plates.

FIG. 9 shows a possible embodiment of this invention comprising a layer of n type thermoelectric material inserted between two electrets of different polarities.

FIG. 9A shows a possible embodiment of this invention comprising a layer of p type thermoelectric material inserted between two electrets of different polarities.

FIG. 10 shows a possible embodiment of this invention comprising a unipolar junction of n/n+ type thermoelectric material.

FIG. 10A shows a possible embodiment of this invention comprising a unipolar junction of p/p+ type thermoelectric material.

FIG. 11 shows a possible embodiment of this invention comprising a Schottky junction between a metal and an n type or a p type material.

FIG. 11A shows a possible embodiment of this invention comprising a hetero-junction.

FIG. 12 illustrates how TDGs can be arranged in a stack to add their respective temperature difference outputs.

FIG. 12A shows how a TDG in combination with a cold sink can be used to implement a heater.

FIG. 12B shows how a TDG in combination with a heat sink can be used to implement a cooler.

FIG. 13 shows a stack of TDGs implemented with electrodes. Adjoining TDGs can combine their electrodes, thereby mutually reinforcing their fields.

FIG. 14 shows a stack of TDGs implemented with p type material and electrets. Adjoining TDGs can combine their electrets, thereby mutually reinforcing their fields.

FIG. 14A shows a stack of TDGs implemented with n type material and electrets. Adjoining TDGs can combine their electrets, thereby mutually reinforcing their fields.

FIG. 15 shows a stack of TDGs implemented with alternately n/n+ and p/p+ insulated junctions. The junctions are mutually reinforcing their fields.

FIG. 16 shows a stack of TDGs implemented with n/n+ or p/p+ insulated Schottky junctions. The junctions are mutually reinforcing their fields.

FIG. 17 shows a stack of TDGs implemented with hetero-junctions. The junctions are mutually reinforcing their fields.

FIG. 18 shows a TDG thermally connected to a Seebeck device, thereby generating electricity.

FIG. 19 shows a stack of TDGs thermally connected to a Seebeck device, thereby generating electricity.

FIG. 20 shows Seebeck devices and TDGs arranged in a circular formation, with cold sinks attached to the cold regions, thereby forcing the assembly to operate above ambient.

FIG. 21 shows Seebeck devices and TDGs arranged in a circular formation, with cold sinks attached to the hot regions, thereby forcing the assembly to operate below ambient.

FIG. 22 illustrates a stack of TDGs connected at their cold end to a cold sink, and attached at their hot end to a Seebeck device. The Seebeck device is terminated by a hot sink. This configuration allows the assembly to run above ambient.

FIG. 23 shows a TDG stack connected in parallel with a Seebeck device. The cold end of the assembly is connected to a cold sink, allowing the assembly to run above ambient.

FIG. 24 shows a TDG stack connected at each end to Seebeck devices. One Seebeck device is connected to a cold sink and the other to a hot sink.

FIG. 25 shows a Seebeck device connected at each end to a stack of TDGs. One stack is terminated by a hot sink, and the other one by a cold sink.

FIG. 26 illustrates a stack of Schottky TDGs terminated at one end by a hot or cold sink, and the other end by a Seebeck device. The Seebeck device is also connected to a hot or cold sink.

FIG. 27 illustrates a ring comprising alternatively, a Seebeck device and a TDG stack. The TDGs utilize n+/n and p/p+ junctions.

FIG. 28 shows an analog of a Crookes' radiometer in which the vanes are kept in a fixed position and the gas particles are allowed to move. Such device, implemented in a semiconductor can generate an electrical current.

FIG. 29 is an inverted version of the one in FIG. 28. A temperature difference is generated in a semiconductor channel by a potential gradient within the semiconductor itself. Propulsion of the gas molecules occurs when thermal equilibrium is broken by an external thermal short circuit.

FIG. 30 illustrates an array of Crookes radiometer analog shown in FIG. 28. Each element of the array is rhombic and contributes to the current being generated.

FIG. 31 illustrates an array of Crookes radiometer analog shown in FIG. 29. Each element of the array has a zigzag shape, and contributes to the current being generated.

FIG. 32 shows an array of fixed-vanes Crookes' radiometer analog oriented perpendicular to the current flow. The matrix is n type material and all TDGs utilize n/n+ junctions formed between the n matrix and embedded n+ layers. The n+ layers are thermally connected to the matrix on one of their sides.

FIG. 33 shows an array of fixed-vanes Crookes' radiometer analog oriented parallel to the current flow.

FIG. 34 shows an array of fixed-vanes Crookes' radiometer analog in which asymmetry is provided by baffles fabricated out of the thermally conducting, electrically insulating material.

FIG. 35 shows two devices of the fixed-vanes Crookes' radiometer kind as shown in FIG. 32. These two devices form a junction. The first device uses an n type matrix, and the second, a p type matrix. Electrons in the n type material are propelled toward the junction, and holes in the p type material are also propelled against the junction. Annihilation of the electrons and holes generates electromagnetic radiation. The electrical circuit is completed by connecting transparent electrodes on either side of the assembly to each other. As heat energy is converted into radiation, heat is replenished by flowing in from the outside.

FIG. 36 illustrates a TDG as small as a single polar molecule.

### DETAILED DESCRIPTION

None of the conventionally known thermoelectric effects explains a puzzling phenomenon sometimes called “dark emf” observed in thermoelectric materials. Often, in the course of measuring the Seebeck coefficient, a temperature difference or a voltage offset is observed in the absence of heat flow or current flow. Essentially, the Seebeck (Voltage vs. Temperature) curve fails to pass through the origin. This effect does not happen all the time but it does happen, sometimes even when the most meticulous experimental procedures are used. Poorly understood, it is usually ascribed to “contact potentials” or “bad experimental procedures” and is viewed as a nuisance in thermoelectric devices and calibrated out of instruments.

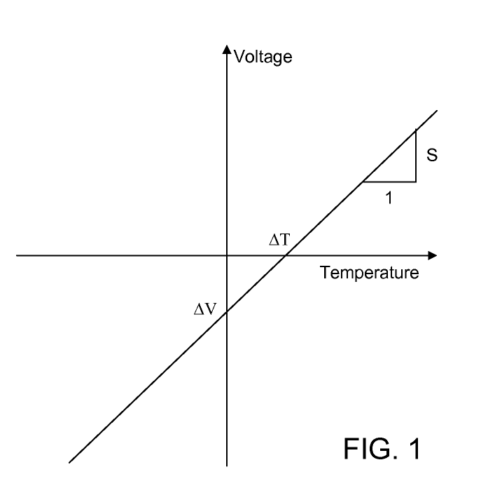

The failure of the Seebeck curve to pass through the origin is illustrated in FIG. 1 and can be expressed by the linear equation

V=S(ΔT−ΔT_{V=0}) (4)

where the intercept with the horizontal temperature axis is ΔT_{V=0}. This intercept indicates that a temperature difference ΔT_{V=0} is measured across a thermoelectric sample without any voltage applied to it and without any heat flow going through the sample. The intersection V_{ΔT=0}=−SΔT_{V=0} of the curve with the Y axis indicates that a voltage is generated even though no current or heat flows through the device. This data has been published but dismissed as experimental or unexplained errors and unrecognized as a useful phenomenon in Iwanaga, S.; Toberer, E. S.; LaLonde, A.; Snyder G. J. A high temperature apparatus for measurement of the Seebeck coefficient. Rev. Sci. Instrum. 2011, 82, 063905-1-063905-6. A theoretical discussion of the phenomenon is provided in Levy, G. Thermoelectric Effects under Adiabatic Conditions, Entropy 2103, 15, 4700-4715; doi:10.3390/e15114700 and also in Levy, G. “Anomalous Temperature Gradient in Non-Maxwellian Gases,” ResearchGate, presented to the 11th International Conference on Ceramic Materials and Components for Energy and Environmental Applications on June 18^{th} held in Vancouver Canada, and will be published after peer review in the conference proceedings.

The invention recognizes that such temperature and voltage offsets are not merely experimental errors but represent a new as yet unrecognized physical phenomenon having a utility rather than being a nuisance. The invention provides a clear explanation for these offsets which are described as a predictable and reliable quantum phenomenon operating on a non-Maxwellian gas exemplified as Fermions such as electron or holes in a semiconductor. In light of the theoretical explanation, the invention proposes device configurations and material selections that amplify these offsets and make them useful for energy production or sensor operation.

Accordingly, a new thermoelectric phenomenon is introduced which describes the behavior of Fermions or Bosons subjected to a potential energy gradient. A first aspect of this phenomenon is characterized by the spontaneous development of a temperature gradient even in the absence of electrical current or heat flow. This aspect is markedly different from the Peltier effect that requires a current.

The second aspect is characterized by the spontaneous development of a voltage in the absence of a temperature difference, and is markedly different from the Seebeck effect which requires a temperature difference.

To reach a good understanding of this topic, one must understand the role that the energy statistical distribution of particles plays in the manifestation of this new effect. It is also useful to emphasize in this regard, the limitation of Classical Physics versus those of Quantum Mechanics. As shall be shown, classical particles which follow Maxwell's distribution cannot spontaneously produce a temperature gradient when subjected to a force field and therefore cannot exhibit the newly discovered effect. Their behavior of these classical particles complies with Classical Mechanics and the Second Law. However, particles that follow Quantum Mechanical (Fermi-Dirac or Bose-Einstein) distributions can spontaneously form such temperature gradients under certain conditions. The remarkable difference between the difference in their distributions. Classical particles follow the Maxwell Boltzmann distribution which is strictly exponential with respect potential energy, and Fermion and Bosons follow distributions which are not strictly exponential. The following paragraphs provide a detailed explanation.

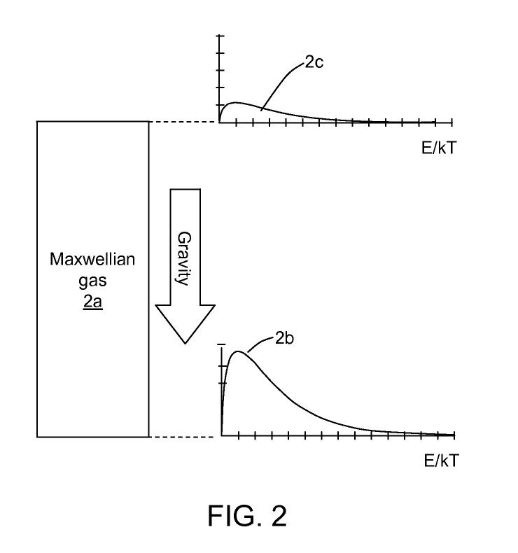

As shown in FIG. 2, a classical Maxwellian gas 2a subjected to a potential energy gradient such as gravity, has a distribution 2b at the bottom of the gradient expressed by:

$${f}_{MB} ( {E}_{k} , {E}_{p} = 0 ) = 2 {( \frac{1}{{k}_{B} T} )}^{3 / 2} \sqrt{\frac{{E}_{k}}{π}} exp ( \frac{- {E}_{k}}{{k}_{B} T} ) \qquad ( 5 )$$

This equation includes three kinds of term. The first is a normalization factor that comprises k_{B}T that ensures that the area under the curve is equal to unity. The second term is in the form of the square root of Eₖ; and the third term is an exponential of Eₖ. At the top of the potential energy gradient, the distribution must include potential energy Eₚ.

$${{f}_{MB} ( v , z )}_{unnormalized} dv = {( \frac{m}{2 π {k}_{B} T} )}^{3 / 2} exp ( - \frac{( {E}_{k} + {E}_{p} )}{{k}_{B} T} ) 4 π {v}^{2} dv \qquad ( 6 )$$

resulting in a denormalized distribution 2c with a lower amplitude indicating a lower density of particles. This equation can be rearranged by moving potential energy under its own exponential.

$${{f}_{MB} ( {E}_{k} , {E}_{p} )}_{unnormalized} = 2 {( \frac{1}{{k}_{B} T} )}^{3 / 2} \sqrt{\frac{{E}_{k}}{π}} exp ( \frac{- {E}_{p} )}{{k}_{B} T} ) exp ( \frac{- {E}_{k}}{{k}_{B} T} ) \qquad ( 7 )$$

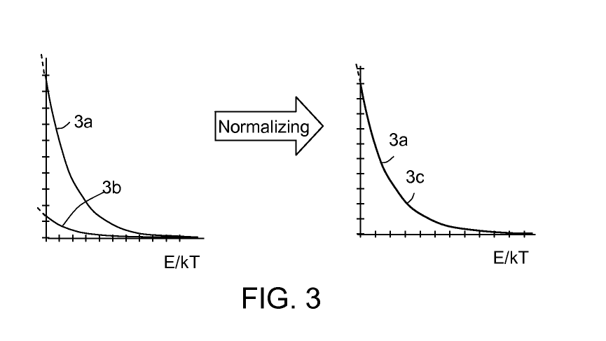

The exponential term in the above distribution is of particular importance in the following discussion. At the bottom of the gradient this term is shown in FIG. 3 as 3a does not include potential energy E_{P} and is expressed as

$$exp ( - \frac{{E}_{k}}{{k}_{B} T} ) \qquad ( 8 )$$

and at the top of the gradient it is shown as 3b and is expressed by

$$exp ( - \frac{{E}_{p}}{{k}_{B} T} ) exp ( - \frac{{E}_{k}}{{k}_{B} T} ) \qquad ( 9 )$$

The addition of potential energy E_{P} corresponds to shifting the distribution along the energy (horizontal) axis. The potential energy term can also be viewed as a factor if it is factored out of the exponential function, thereby corresponding to a scaling change along the number of particles (vertical) axis.

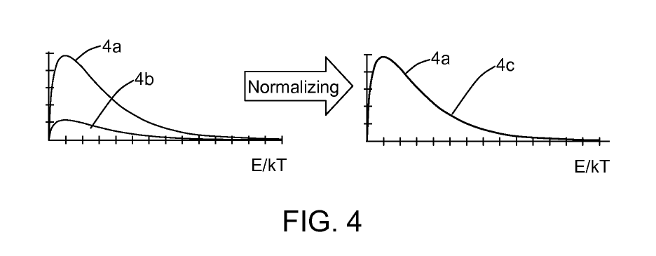

The distributions expressed in equations (6) or (7) can be used to calculate the temperature of the gas at the bottom and at the top of the column. Temperature represents the average kinetic energy of particles, and therefore, can be obtained by calculating the first moment of the normalized distribution. When the distribution at the top is normalized, converting it to a probability as shown in FIG. 4, the potential energy term E_{P} which factored out in (7) is eliminated, yielding

$${{f}_{MB} ( {E}_{k} )}_{normalized} = 2 {( \frac{1}{{k}_{B} T} )}^{3 / 2} \sqrt{\frac{{E}_{k}}{π}} exp ( \frac{- {E}_{k}}{{k}_{B} T} ) \qquad ( 10 )$$

resulting in the distribution 4c at the top of the energy gradient, identical with the distribution 4a at the bottom of the gradient, indicating that the distribution is independent of the potential energy term E_{P}. The corresponding normalized exponential term is shown as 3c in FIG. 3 and is identical to the original exponential 3a.

The exponential expression of potential energy in the Maxwell distribution specifically implies that the average kinetic energy of a gas particle is invariant with elevation, and the gas is isothermal in conformance with the Second Law. (One should note that this uniformity does not apply to the density of the gas, which decreases exponentially with elevation). Stepping back momentarily from this statistical analysis, this temperature invariance can be viewed as the cancellation of two opposite effects. The first, due to the conversion of kinetic energy into potential energy in rising particles, tends to reduce the temperature of the gas with elevation. The second effect separates particles according to their total energy in a manner analogous to that of a mass spectrometer separating particles according to their mass. This second effect favors more energetic and hotter particles to move upward. In classical gases that follow the Maxwell-Boltzmann distribution, these two effects cancel each other out exactly resulting in the gas being isothermal.

In non-Maxwellian gases, however, the potential energy term is not cancelled by the normalization process because potential energy is not expressed as a strict exponential function. Such gases exemplified by Fermions (e.g., electrons or holes) in a semiconductor can therefore spontaneously develop a temperature difference when subjected to a potential energy gradient.

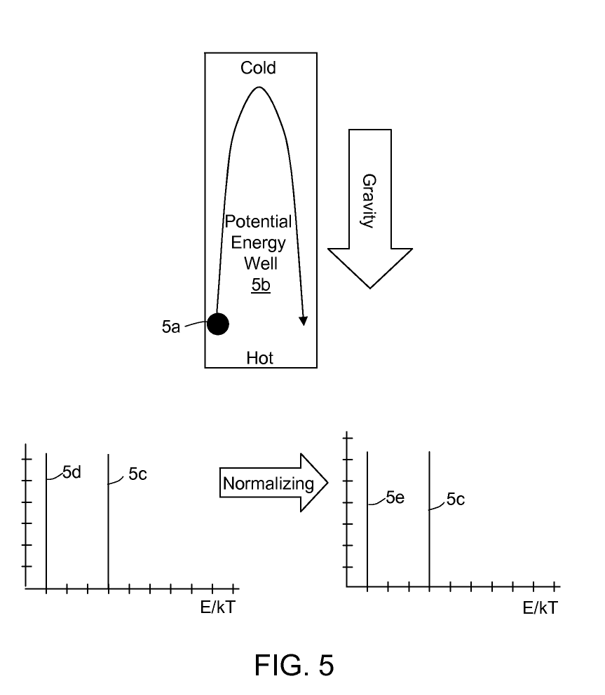

The impulse distribution shown in FIG. 5 is a simple non-Maxwellian example that illustrates the effect. For the purpose of this discussion, we shall consider a perfectly elastic ball 5a bouncing in an energy well 5b with a perfectly rigid, elastic and motionless floor, walls and ceiling. Since the total energy of the ball is single valued and invariant, the energy distribution is an impulse. At the bottom of the energy well, the ball has a higher kinetic energy 5c and a lower potential energy and, conversely, at the top of the well, it has a lower kinetic 5d energy and a higher potential energy. Hence the temperature of the ball decreases with elevation. Normalization of the distribution does not eliminate the potential energy term as was the case with the Maxwell distribution. Normalizing the distribution near the ceiling produces 5e but does not change its relationship with the normalization near the floor 5c confirming that the temperature of this single gas particle decreases with elevation. A physical embodiment of an impulse distribution can be found in a Bose-Einstein condensate in which all particles have exactly the same (ground state) energy for a given elevation.

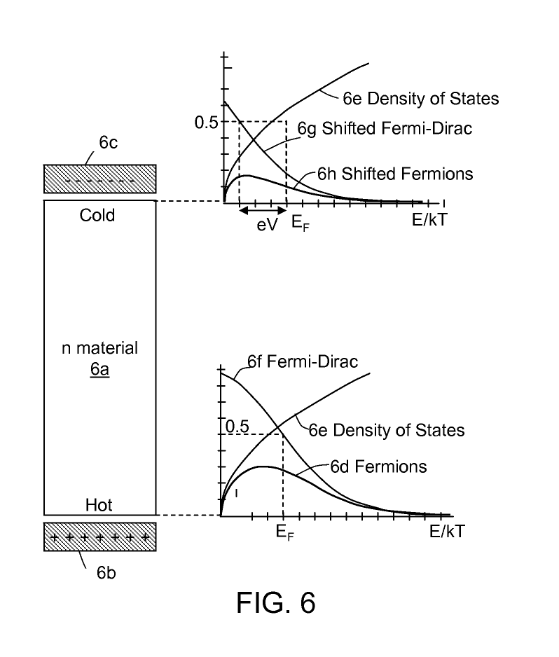

Physical systems embodying Fermions or Bosons can also produce temperature and voltage differentials. FIG. 6 illustrates Fermions embodied by electrical carriers in a semiconductor 6a subjected to an electrical field, as could be supplied, for example, by insulated capacitor plates 6b and 6c. At the bottom of the potential energy gradient, the kinetic energy distribution 6d of the carriers is the product of their density of state 6e and their Fermi-Dirac distribution function 6f. At the top of the gradient, the Fermi-Dirac distribution is shifted 6g by the additional potential energy, thereby generating an altered Fermion energy distribution 6h. This can be expressed as a function of the applied potential V as

$${f}_{FD} ( {E}_{k} , V ) = A ( V ) \sqrt{{E}_{k}} \frac{1}{1 + exp ( \frac{{E}_{k} + ( - e ) V + {E}_{c} - {E}_{F}}{{k}_{B} T} )} \qquad ( 11 )$$

where A(V) is a normalization factor given by:

$$A ( V ) = {[ {\int }_{0}^{∞} \sqrt{{E}_{k}} \frac{1}{1 + exp ( \frac{{E}_{k} + ( - e ) V + {E}_{c} - {E}_{F}}{{k}_{B} T} )} d {E}_{k} ]}^{- 1} \qquad ( 12 )$$

E_{c} is the conduction band energy, and E_{F} is the Fermi level. The distribution for holes can be described by analogous equations that refer to the valence band instead of the conduction band.

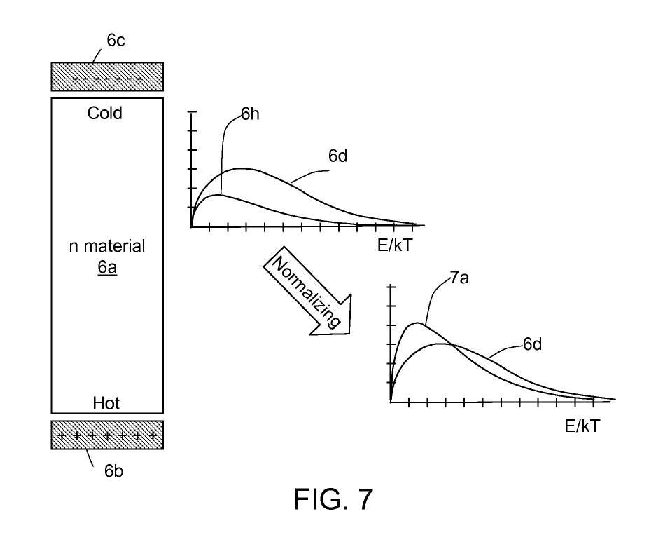

The distribution 6h at the top of the gradient indicates a lower particle density than at the bottom 6d. However, as shown in FIG. 7, after normalization the distribution at the top 7a differs from that at the bottom 6d, indicating a shift toward the left of the first moment. In other words the temperature of the gas decreases with elevation. This behavior is markedly different from that of a Maxwellian gas which was shown in equation (10) and in FIGS. 2-4 to be isothermal with elevation.

An analogous behavior occurs with Boson gases which are non-Maxwellian.

These temperature gradients become more pronounced when certain conditions are met:
1. Non-Maxwellian particles must be present and must be in a gas phase. Such particles include Fermions or Bosons.
2. The particles must be subjected to a potential energy gradient. This gradient could be produced in a number of ways, for example by a field or by a phase change. A field can arise in the presence for example of a doping gradient, an n+/n junction, a p+/p junction, a Schottky junction or a change in the Fermi level. The field can also be externally generated, for example, by electrets or electrodes on either side of, and insulated from, the material. Potential energy gradients can also be produced by phase changes.
3. The dimension of the active layer should preferably be small enough that the potential energy gradient is maintained. For example, if this gradient is produced by an electrical field, no significant space charges should be allowed to accumulate in the material as the space charges would cancel the field in the bulk which would then become unproductive. In other words, the active layer is the region where there exists a potential energy gradient and additional material thickness is unneeded. The reduction or elimination of space charges can be achieved by scaling down the thickness of the material layer to the order of the mean free path of the charge carriers. (i.e., use of ballistic carriers). If the gradient is produced by a phase change, then the thickness of the device should approximately span the region of phase change.
4. The material should have a high ZT coefficient to reduce thermal short produced by heat phonons travelling through the crystal lattice. Such materials are commonly known in the field of Thermoelectricity. They include but are not restricted to Bismuth chalcogenides such as Bi₂T₃ and Bi₂Se₃, Thallium doped Lead Telluride PbTe, Inorganic clathrates, and skutterudites. For a list of thermoelectrics and their properties the readier is referred to the technical literature, including the patents that have been incorporated by reference. The concept of ZT coefficient, traditionally applied to Fermions in a thermoelectric material, is expanded to include non-Maxwellian particles. The reason for the high ZT is to maximize heat transfers by particles such as Fermions or Bosons which are subjected to the potential energy gradient (or field) and minimize heat transfers by particles which are not subjected to the potential energy gradient, for example, heat phonons in the crystal matrix.
5. The carrier density should be high enough to allow interactions between them (e.g., scattering) thereby permitting them to develop their own non-Maxwellian statistical distribution. This high density can be controlled by adjusting the doping level.
6. The configuration should preferably and if applicable, take into account the different modes of heat flow. If a junction is used to produce the field, then the junction should be unipolar (i.e., n/n+ or p/p+) or Schottky (n/metal, p/metal). Heterogeneous junctions (e.g., Si/Ge) can also be used because their different Fermi levels can produce a potential energy gradient. Bipolar (n/p) junctions would not be adequate as electrons and holes subjected to the same field have opposite potential energy gradients and therefore produce opposite temperature gradients and opposite heat flows.

The conditions outlined above can be embodied by a large number of architectures which shall be classified as follows:
1. Temperature Difference Generators in which the potential energy gradient is produced by an external field. These shall be called E-TDGs.
2. Temperature Difference Generator in which the potential energy gradient is internally generated or “built-in.” These shall be called I-TDGs.

### Effective Temperature Versus Actual Temperature

As explained above, an actual temperature gradient arises spontaneously in non-Maxwellian gases subjected to a potential energy gradient. This potential energy gradient can be produced by an electrical field if the gas particles are electrical carriers. This actual temperature gradient represents a state of thermal equilibrium as it is not accompanied by any heat flow. In such a state, the gas has an effective temperature gradient defined as being zero. Conversely, heat flows when the effective temperature gradient is not zero. Thus effective temperature is defined as a function of heat flow and in non-Maxwellian gases it is different from actual temperature.

This also implies that when actual temperature in a non-Maxwellian gas is equalized, effective temperature acquires a gradient, inducing heat to flow through the column. When a non-Maxwellian gas column subjected to a downward force field is thermally shorted by connecting its top and bottom by means of a Maxwellian gas column or by using particles not susceptive to the field (e.g., heat phonons in a semiconductor), heat is induced to flow through the non-Maxwellian column from its cold top to its hot bottom and through the shorting column from its hot bottom to its cold top. Thermal equilibrium is never reached. This effect does not exist in Maxwellian gases because the actual temperature and the effective temperature are the same.

### Temperature Difference Generators Using External Fields (E-TDGS)

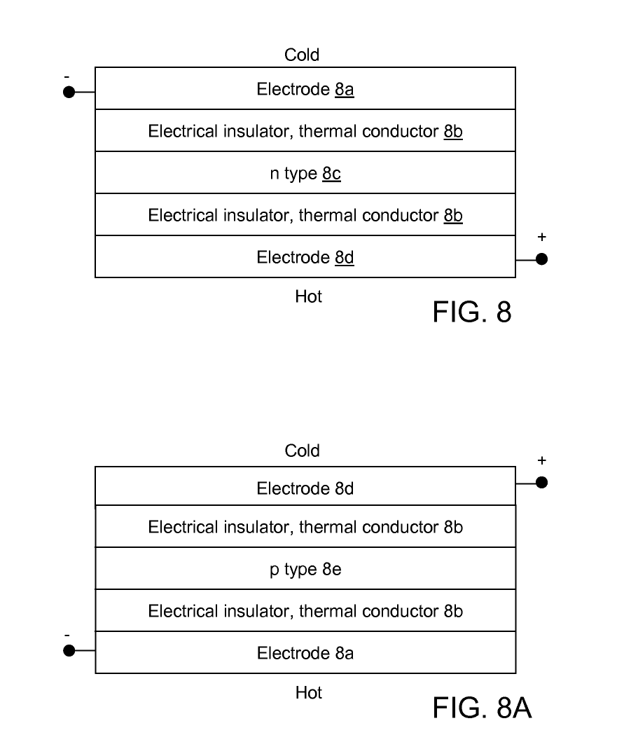

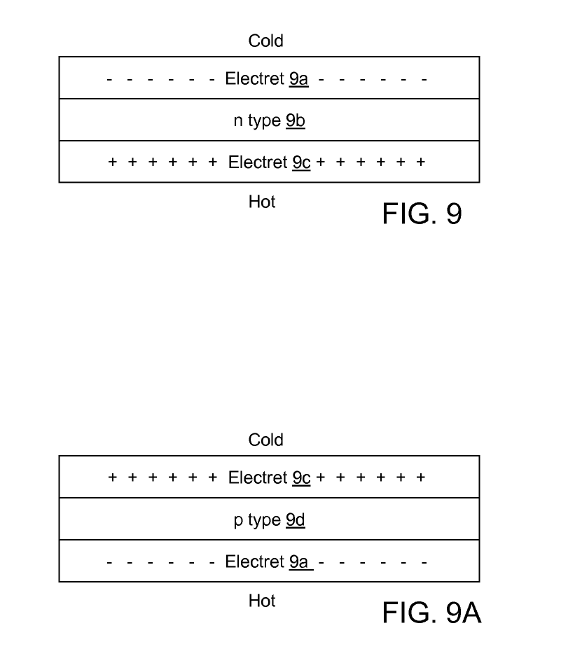

FIGS. 8-9A illustrates some configurations for E-TDGs. FIG. 8 shows a layer of n material 8c inserted between, and insulated from, capacitor plates 8a. The electric field traversing the n material 8c causes the negatively charged carriers to have a higher potential energy near the negative electrode 8a and a higher kinetic energy near the positive electrode 8d, resulting in a higher temperature at the positive electrode 8d. To prevent current flow, the electrodes 8a and 8d are coated with electrically insulating, thermally conductive layers 8b or separated by means of a gap from the n type material 8c. Optionally they can also be coated on the outside with an insulating layer. The insulating layers 8b comprise but are not limited to Barium Fluoride, Aluminum Oxide (sapphire), diamond, Silicon Nitride and Silicon Dioxide. Insulating layers can also comprise organic materials such as polyimide (Kapton®)

The principle illustrated in FIG. 8 also works with a p type material as shown in FIG. 8A. A layer of p material 8e is inserted between and insulated from, capacitor plates 8a and 8d. The insulation can be in the form of layers 8b or gaps. The temperature difference is opposite to that in FIG. 8 because of the opposite polarity of the carriers. One can notice from FIGS. 8 and 8A that these two devices can easily be stacked, merging electrodes 8d together, to add the temperature difference produced by each device. This topic of stacking or combining TDGs shall be further discussed below.

FIG. 9 shows a layer of n material 9b between two oppositely charged electret layers 9a and 9c, resulting in the positive electret 9c being hotter than the negative electret 9a.

FIG. 9A shows a layer of p material 9d between two oppositely charged electret layers 9a and 9c, resulting in the negative electret 9a being hotter than the positive electret 9c. One can easily notice from FIGS. 9 and 9A that these two capacitive devices can easily be stacked, merging electrets 9c together to add the temperature difference of each element. If a device operates independently of a stack, each electret layer can be unipolar. If the devices are stacked, the electret layers may optionally be bipolar depending on the type of material being stacked (i.e., n/n+/p/p+vs. n/n+/n/n+.) This topic shall be further discussed below.

### Temperature Difference Generators Using Internal Fields (I-TDGS)

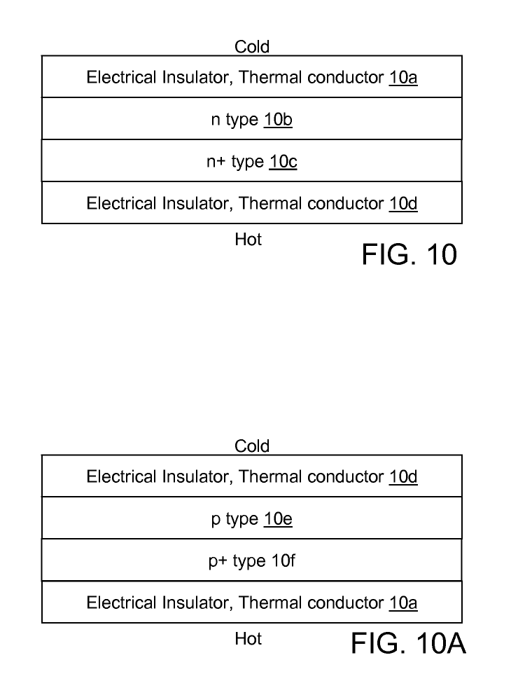

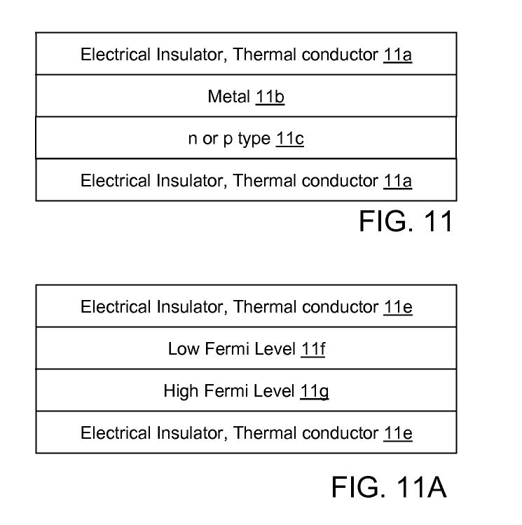

FIGS. 10, 10A, 11, 11A and 11B illustrate some I-TDG configurations wherein the field is produced internally by a junction.

FIG. 10 illustrates a device in which the field is produced by a unipolar junction comprised of n/n+ material 10b and 10c respectively. Electrons lose kinetic energy as they move away from the positive charges left behind in the more heavily doped layer 10c and therefore, the layer 10b is colder than the layer 10c. The device is optionally coated on either side by electrically insulating and thermal conducting layers 10a and 10d, as the main purpose of the device is to produce a temperature difference and not a current.

FIG. 10A illustrates a device in which the field is produced by a unipolar junction comprised of p/p+ material 10e and 10f respectively. Holes lose kinetic energy as they move away from the negative charges left behind in the more heavily doped layer 10f and therefore, the layer 10e is colder than the layer 10f. The device is optionally coated on either side by electrically insulating and thermal conducting layers 10a and 10d, as the main purpose of the device is to produce a temperature difference and not a current. The devices of FIGS. 10 and 10A can be stacked by merging the layers 10d together to obtain a larger temperature difference. One should note that stacking these devices in this fashion reinforces their fields because the positive fixed charges in the n+ layer 10c affect the holes in the p layer 10e and, vice versa, for a stack with more then 2 elements, the fixed charges in the p+ layer 10f affect the charges in the n layer 10b.

FIG. 11 illustrates a device in which the field is produced by a Schottky junction. The direction of the temperature gradient depends on the difference in the Fermi potentials between the n or p type material 11c and the metal 11b, and on the polarity of the carriers. This device can also be stacked to increase the useful temperature difference.

FIG. 11A illustrates a device in which the potential energy gradient is produced by a heterogeneous junction formed between a low Fermi energy material 11f and a high Fermi energy material 11g. The direction of the temperature gradient depends on the difference in the Fermi potentials and the polarity of the carriers. This device can also be stacked to increase the useful temperature difference.

The energy gradient can also be produced by quantum wells, quantum dots. The reader is referred to the vast literature on thermoelectrics.

### Stacking Temperature Difference Generators

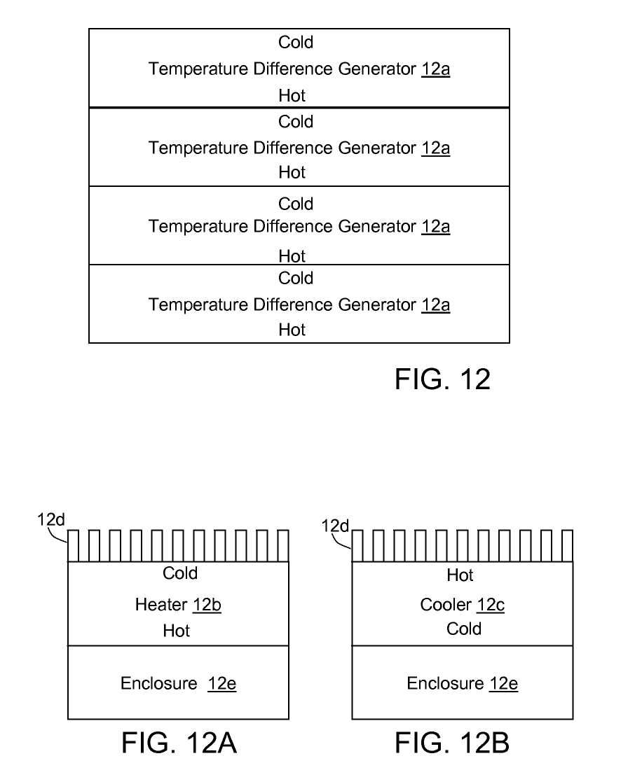

The output of a temperature difference generating device (I-TDGs and E-TDGs shown in FIGS. 8 to 11B) can be multiplied by stacking a multiplicity of them such that the hot face of one device 12a is in contact with the cold face of the abutting device as illustrated in FIG. 12 (except, of course, at the end of the stack).

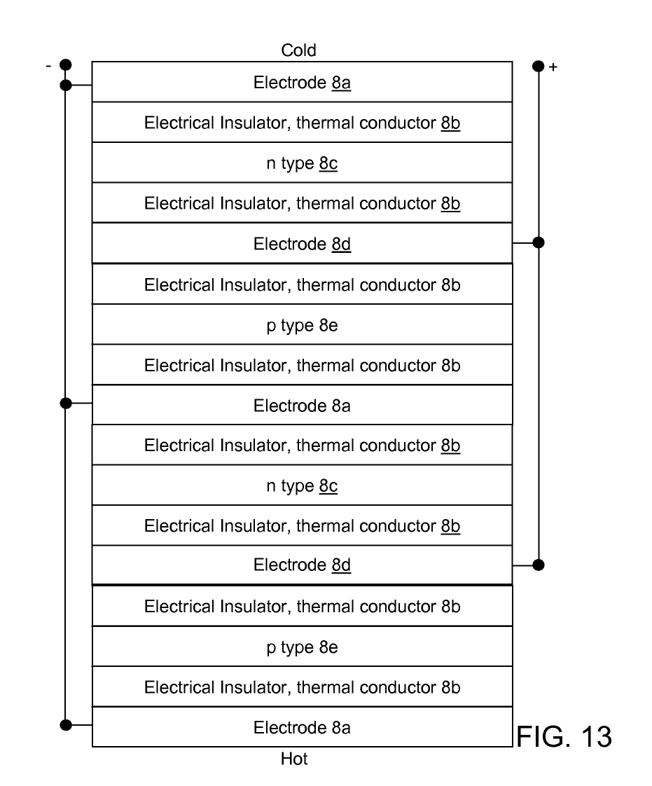

Devices relying on an electrical field to produce a potential energy gradient are likely to be polarized. In addition if the stacked devices rely on an internally generated field, then each device should preferably reinforce the field of the adjacent devices. Therefore, the stack should be configured such that each face of a device abuts an adjacent device's face with the same polarity. The stacking configuration preferably allows for the positively charged face of one device to be in contact with the positively charged face of the abutting device thereby reinforcing the field traversing each device. For example, if n type devices shown in FIG. 8 are interleavingly stacked with p type devices shown in FIG. 8A, then the negative electrode 8a of one stack element should be merged with the negative electrode 8a of the abutting stack element. Similarly, the positive electrodes 8d of abutting stack elements should be merged (except at the top and bottom of the stack of course). This stacked configuration is shown in FIG. 13. This configuration allows each stack element to mutually reinforce their fields.

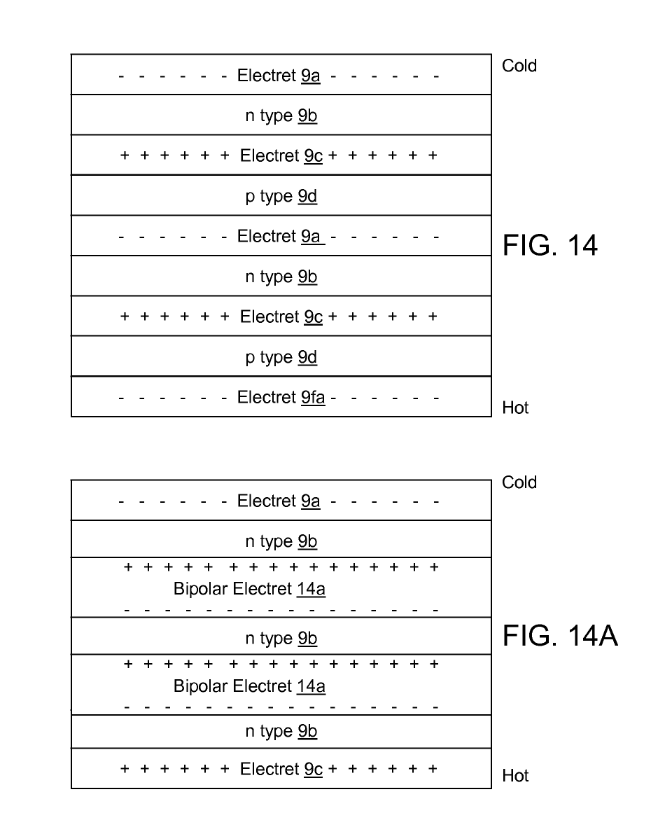

Similarly if electret-based devices such as shown in FIG. 9 are stacked interleaving n type and p type devices, then the electrets 9a belonging to an n type device should be merged with the electret 9a belonging to a p device as shown in FIG. 14 (except at the end of the stack of course). The electrets could be independent layers or could be insulating layers with the charges embedded in the n or p materials.

If the stack only comprises n type devices or p type devices, then bipolar electrets can be used as shown in FIG. 14A.

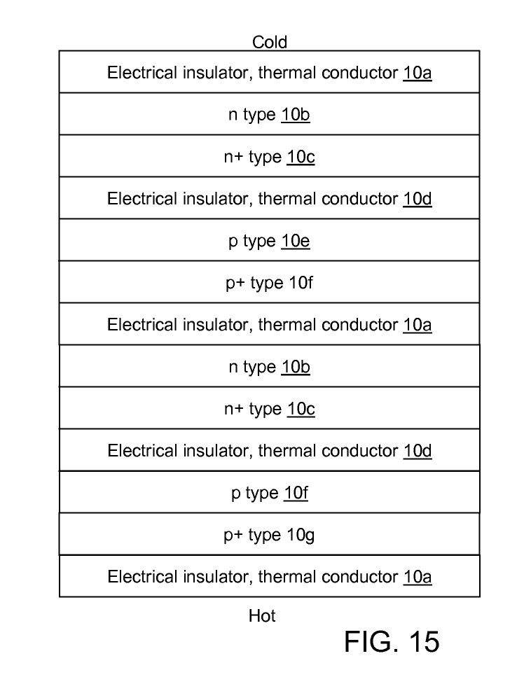

The same reasoning applies to the devices of FIGS. 10 and 10A which can be stacked by combining the electrically insulating thermally conducting layers 10a from an n type device with the layer 10a from a p type device, and the layer 10d from an n type device with the layer 10d from a p type device. Stacking these devices in this fashion as shown in FIG. 15 reinforces their fields because the positive fixed charges in the n+ layer 10c affects the holes in the p layer 10e and, vice versa, for a stack with more than 2 elements, the fixed charges in the p+ layer 10f affect the charges in the n layer 10b.

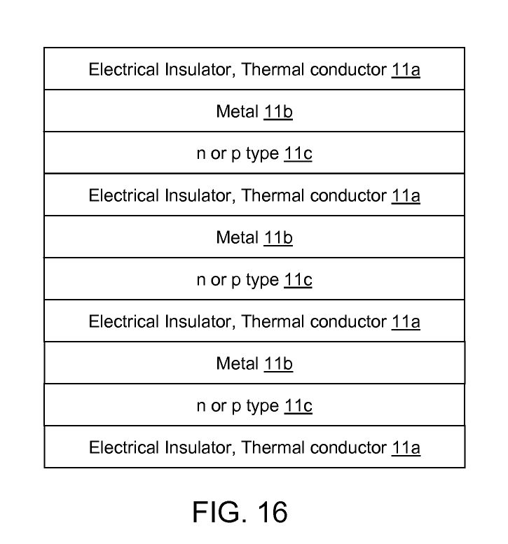

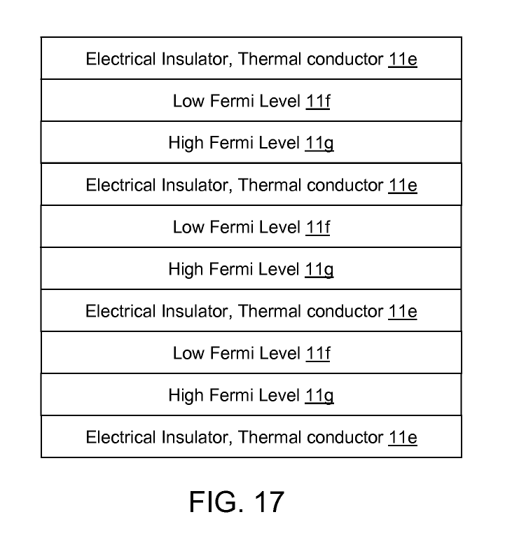

Similarly, a multiplicity of Schottky devices can be stacked as shown in FIG. 16, as well as a multiplicity of heterojunction devices as shown in FIG. 17. The semiconductor material can be n or p type.

One should recognize that in a stack arrangement, different layers in the stack can operate at different temperatures and, therefore, for an optimum design, the design parameters for each layer may be different. Design parameters include but are not restricted to, type and amount of doping, type of semiconductor material, and the area and thickness of the device.

### Application of Temperature Difference Generators for Cooling and Heating

The TDGs described above, either singly or in stacks, can be used as coolers or heaters. For example, as shown in FIG. 12A, connecting the cold end of a TDG stack to a cold sink 12d exposed to the environment, would produce a heater 12b as heat would flow into the cold sink 12d from the environment, through the stack and exit at the uncovered hot end of the stack thereby raising the temperature in an enclosure 12e. Conversely, as shown in FIG. 12B, connecting the hot end of a TDG stack to a hot sink would produce a cooler 12c as heat would flow from the enclosure 12e into the stack, into the hot sink 12d and exit into the environment thereby lowering the temperature in the enclosure 12e.

Such heaters and coolers can be used in a wide range of applications that includes but is not limited to electronics cooling, food and drink preservation, space heating, air conditioning, water heating etc. The TDGs can also be connected to a heat engine such as a Seebeck device to generate electricity. Assemblies of TDGs and Seebeck devices could also be electrically strung together in series such that the Seebeck voltages add up.

TDGs configured in film can be used to form a container for example to make a cooler or a heater. Depending on how the layers of thermoelectric material are arranged, this container can operate as a heater or as a cooler without the need for a power input. The TDGs that employ externally generated fields can also be used to make controllable heater or cooler systems.

### Combining Temperature Difference Generators with Seebeck Devices

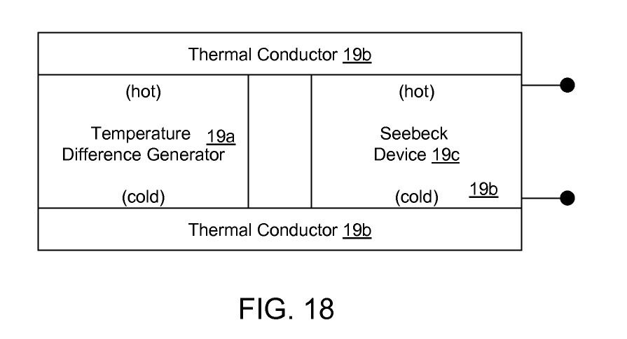

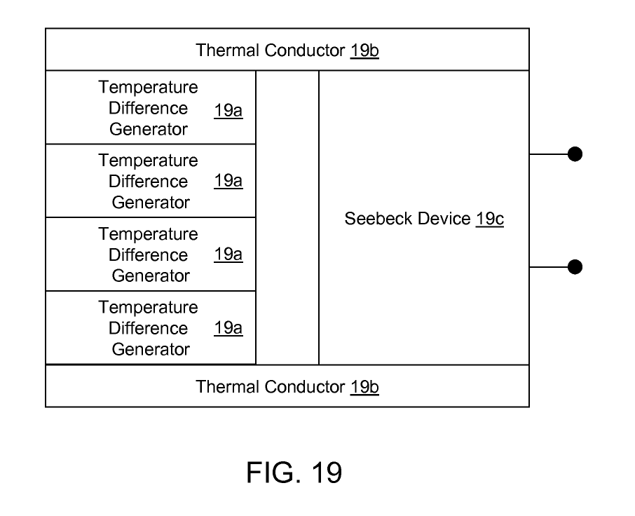

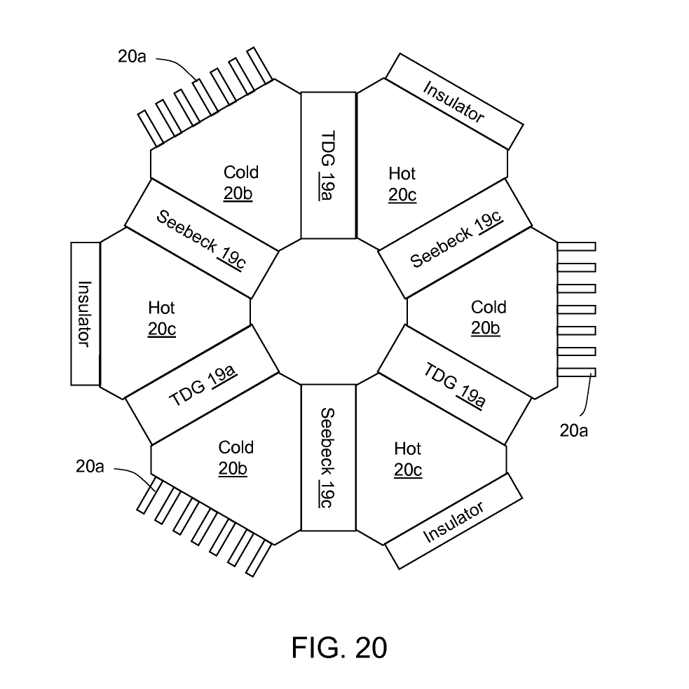

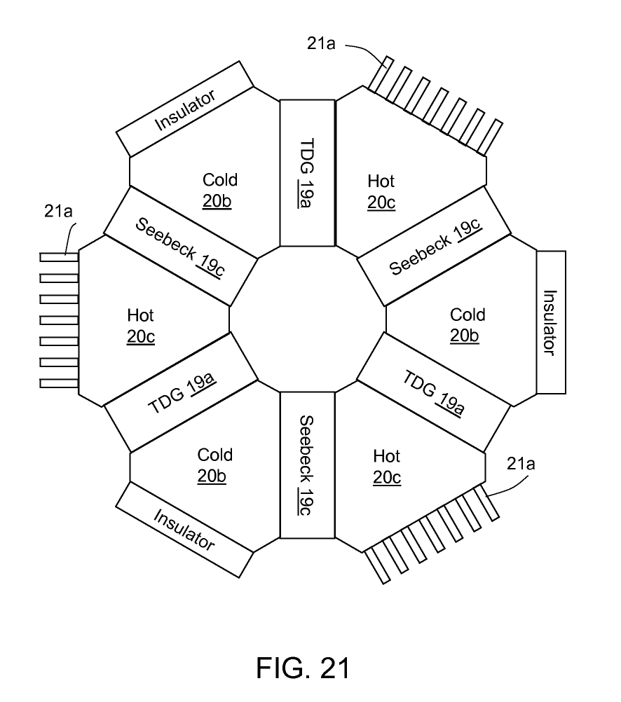

There is a multiplicity of ways TDGs can be combined, stacked and interleaved with Seebeck devices to produce electrical energy. FIGS. 18-21 illustrate some of these configurations. In FIG. 18 the TDG 19a is connected by means of thermal conductors 19b to a Seebeck device 19c. The hot output faces of the TDG 19a is thermally connected to the hot input face of the Seebeck devices 19c, and the cold output face of the TDG 19a, to the cold input face of the Seebeck device 19c. FIG. 18 illustrates the basic idea including a single TDG. FIG. 19 shows a stacked configuration. FIG. 20 depicts a circular arrangement, in which cold sinks 20a are used to replenish heat energy converted to electrical energy and to bring the cold thermal conductors 20b of the device to ambient temperature, thereby allowing the device to operate above ambient. FIG. 21 shows how cold sinks 21a can be placed to bring the hot thermal conductors 20c of the device to ambient, thereby allowing the device to operate below ambient.

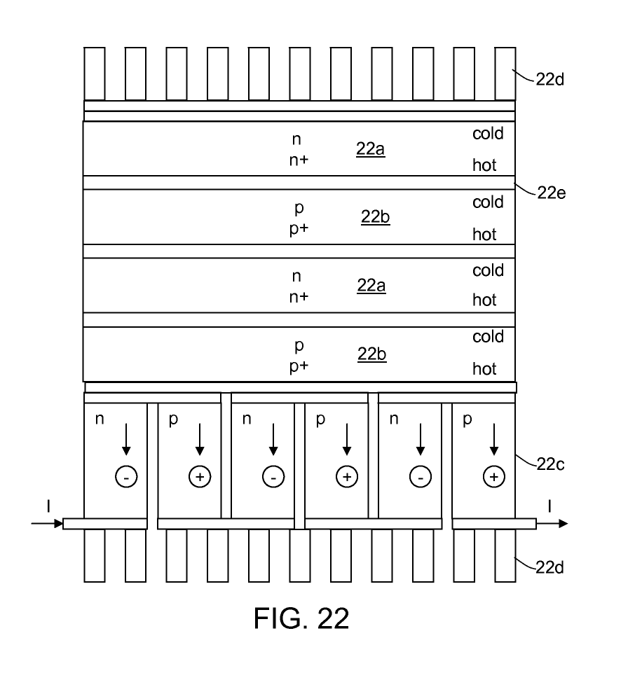

FIGS. 22-26 illustrates several architectural variations for connecting n/n+TDGs 22a and p/p+TDGs 22b in a stack and with Seebeck devices 22c. In FIG. 22, the TDGs 22a and 22b are arranged in a stack separated by electrically insulating thermally conductive layer 22e. The Seebeck devices 22c are located at one end of the stack. Cold sinks 22d are located at each end to replenish heat energy converted to electricity.

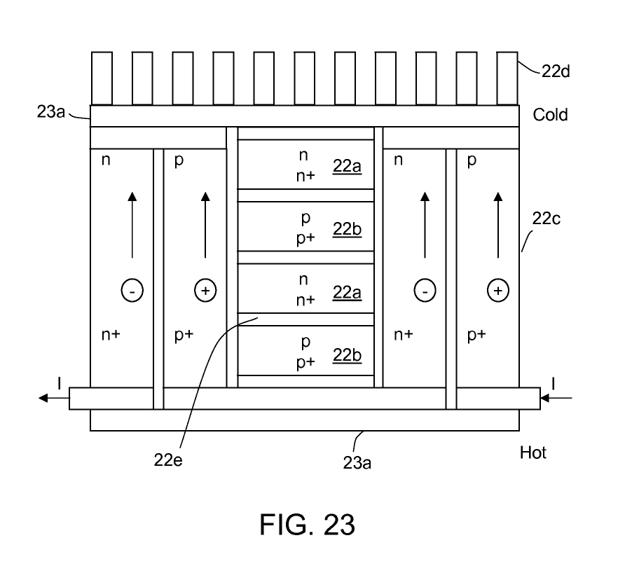

In FIG. 23 the ends of the stack of n/n+TDGs 22a interleaved with p/p+TDGs 22b is in contact with electrically insulating, thermally conductive plates 23a. Seebeck devices on either side of the stack are also in contact with the plates 23a, thereby closing the thermal loop.

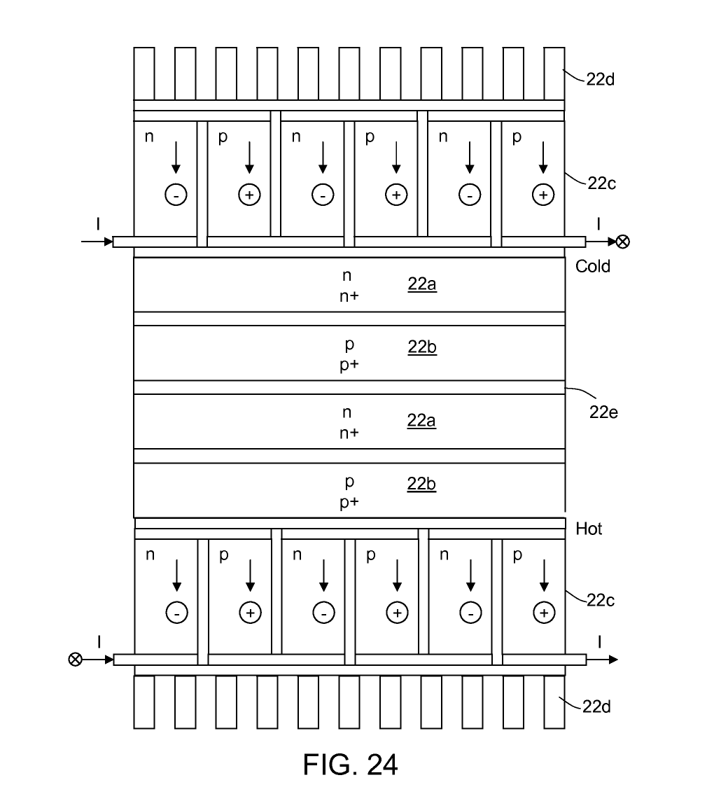

In FIG. 24 the stack of n/n+TDGs 22a interleaved with p/p+TDGs 22b is terminated at both ends with Seebeck devices 22c. The Seebeck devices 22c are connected to cold sinks 22d.

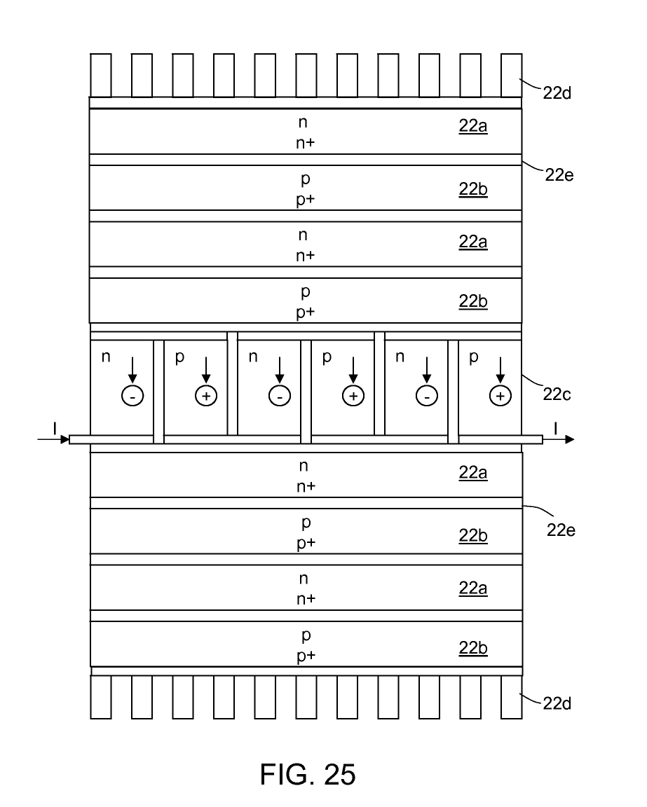

In FIG. 25 the Seebeck devices 22c are centrally located. Stacks of n/n+TDGs 22a interleaved with p/p+TDGs 22b are positioned on either side of the Seebeck device assembly 22c. Cold sinks 22d connected to the external end of each stack allows ambient heat to replenish heat energy converted to electricity.

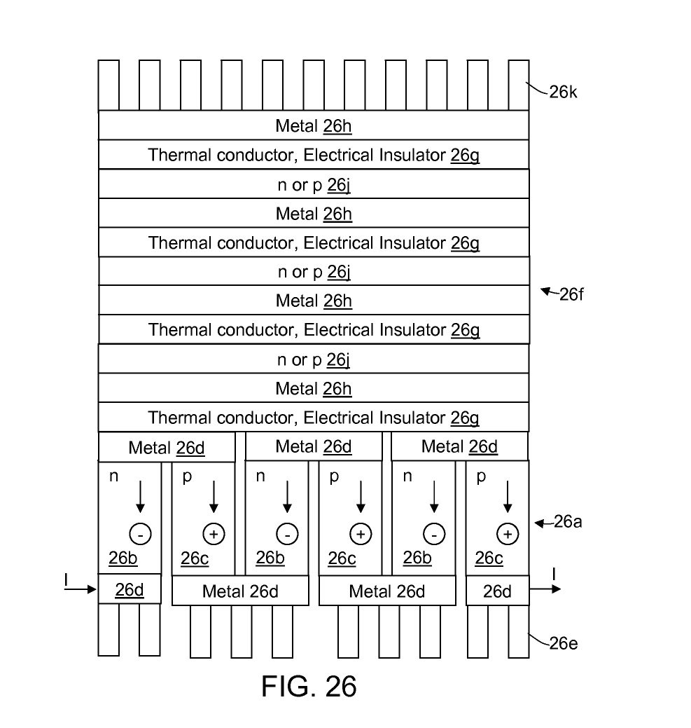

FIG. 26 provides an example of a Seebeck device 26a which is driven by the temperature difference generated by a TDG comprised of Schottky junctions. The Seebeck device includes a series of n and p legs 26b and 26c respectively, electrically connected in series by metal plates 26d and thermally connected in parallel between a cold sink 26e and a stack of TDGs 26f. The stack comprises a succession of thermal conductive, electrically insulative layers 26g, metal layer 26h, and semiconductor layer 26j. The stack ends with a heat exchange device 26k. The TDG is hot at one of its ends and cold at the other depending on the direction of the energy gradient between the semiconductor 26j and the metal 26h. One can control the temperature of operation of the Seebeck device and the TDGs by changing the ratio of the sinks' heat transfer capacity or simply eliminating one of the sinks.

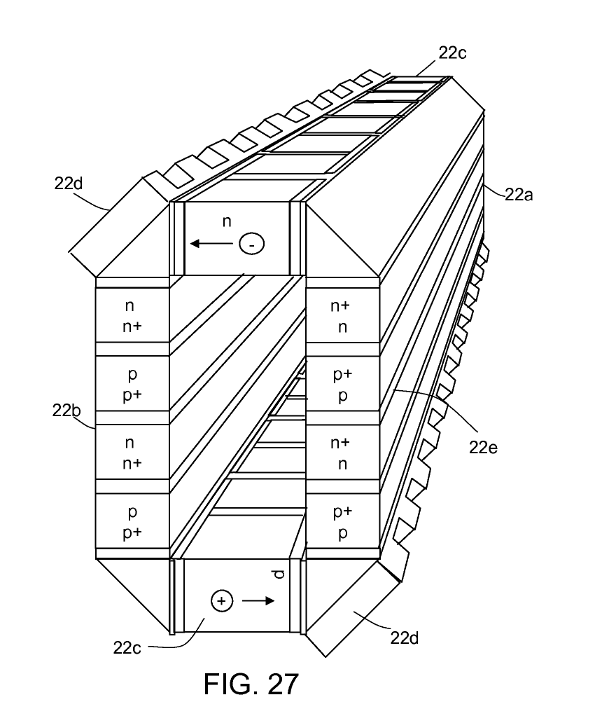

In FIG. 27 stacks of n/n+TDGs 22a and p/p+TDGs 22b and Seebeck assemblies 22c are arranged in a loop in an alternating order.

### Immobilized Crookes Radiometer Energy Generation

As discussed above, energy can be generated by connecting a temperature difference generator to a Seebeck device.

Another approach is to utilize the temperature difference produced by a TDG to induce a current flow in a manner analogous to a Crookes radiometer. Before discussing particular embodiments, a short review of the radiometer is presented to familiarize the reader with this device. The Crookes radiometer or light mill was invented in 1873 by Sir William Crookes. It consists of a glass bulb filled with a partial vacuum of about 60 μHg, and an impeller comprised of four rotating vanes mounted on a spindle. The vanes are typically made of mica, a thermally insulating material, and are coated on one of their sides with a dark, light-absorbing material such as carbon black, and on the other side, with a light-reflecting or white material. When the radiometer is exposed to light, a temperature differential is produced between the vanes' surfaces causing the impeller to rotate, the dark side moving away, and the white sides advancing against, the light source.

Many famous scientists have contributed to the explanation of this effect, the most authoritative to date is Osborne Reynolds who provided a mathematical treatment of the phenomenon. Molecules rebounding from the hot black surface have more energy and speed and therefore impart more momentum to the surface than molecules rebounding on the cold white surface. This momentum transfer results in a movement of air molecules around the edges of the vanes which produces a force on the vanes.

Essential features of the Crookes radiometer include:
1. Impeller vanes made of thermally insulating material such as mica to ensure that a useful temperature difference can develop between the vanes' faces. (Please note that when the actual temperature difference is internally produced by a TDG, then the material needs to be a thermal conductor to produce an effective temperature difference, as shall be discussed below).
2. The two faces of each vane capable of absorbing light differently, for example by being black and white;
3. A light source capable of producing a temperature difference between the faces; (A Crookes radiometer device described in this invention relies on an effective temperature difference produced by thermally short circuited TDGs. As discussed above, effective temperature and actual temperature are different in a non-Maxwellian gas) and
4. A gas with a pressure low enough that the mean free path is between about one to three orders of magnitude smaller than the dimensions of the vanes. In a typical radiometer the pressure is about 60 μHg resulting in a mean free path of about 0.6 mm, and the vanes are about 10 mm square corresponding to a ratio of 16. (Even though a better match between the vanes' dimension and the mean free path may improve the momentum transfer per molecule, a slightly smaller mean free path corresponding to a higher pressure and molecular density improves the overall momentum transfer. Hence the preferred ratio in the conventional Crookes radiometer is about 16).

In a radiometer, a radiantly produced temperature difference across the vanes propels the gas in the radiometer bulb (giving rise to a reactive force that makes the vanes rotate.) In fact, even if the vanes of a Crookes radiometer were immobilized the gas would still be propelled around the bulb. This phenomenon is remarkably analogous to the Seebeck effect in which a temperature difference produces a current, but it is also different because the Seebeck effect is convective in nature whereas the radiometer effect critically depends on the low gas pressure and the length of the mean free path in relation to the vanes' dimensions. The reader is directed to the paper by Reynolds for a better understanding of the criticality of the low gas pressure, the mean free path and the dimension of the vanes. The conditions outlined above of low pressure and dimensional relationship between the scale of the device and the mean free path, can be properly adapted to a semiconductor environment for generating electrical energy. The radiometer effect, therefore, is a new thermoelectric paradigm that can be used to produce useful electrical energy.

The Fermions' ability to develop a temperature gradient in a field can be used in a semiconductor analog version of a radiometer, to convert ambient heat into useful energy. In a conventional radiometer, a temperature differential is produced because radiant energy is absorbed by the darkened side of the vanes. This temperature differential propels the dilute gas in the radiometer bulb away from the darkened sides, generating a reactive force and making the vanes rotate. An analogous effect can be generated in a semiconductor. A temperature differential can be generated when electrical carriers (which comply with the Fermi-Dirac distribution) are subjected to a force field. This temperature differential can propel the carriers thereby generating an electric current. Requirements for the Crookes' radiometer effect to operate in semiconductors include high ZT material (e.g., low coupling between electrical carriers and the solid matrix) and dimensions scaled to the mean free path of the particles in analogy to a radiometer. In addition, a potential energy gradient must be present to produce a temperature difference in the electrical carriers as already discussed above. Furthermore the carriers' density should be high enough for the carriers to interact, for example through scattering, thereby developing their own statistical distribution.

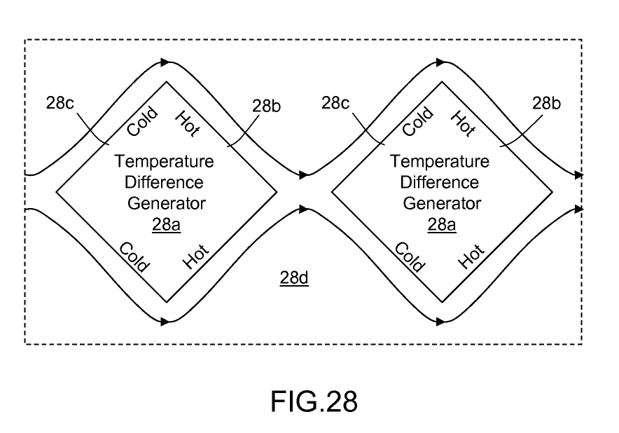

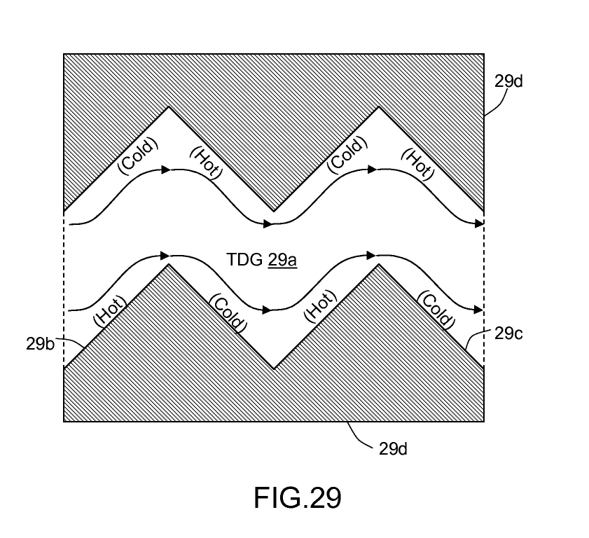

FIGS. 28 and 29 present two alternative basic embodiments of the radiometer effect in semiconductors. FIG. 28 is a direct analog of the immobilized Crookes radiometer with fixed vanes. The black/white vanes are replaced by the temperature difference generators 28a with faces arranged 90 degrees from each other, thereby producing a current. The TDGs are embedded in a semiconductor matrix 28d, capable of supporting electrical carriers. The carriers are propelled away from the hot faces 28b of the TDG and toward the cold faces 28c, in analogy to the radiometer in which gas molecules are pushed away from the black surfaces and toward the white surfaces. The TDG has a rhombic cross-section to streamline gas flow and is configured to utilize the techniques already discussed above to produce a temperature difference. The potential energy gradient can be produced by electrodes and electrets, as well as with unipolar, Schottky and heterogeneous junctions. The cross-sectional shape of the device does not have to be rhombic, for example a circular or rectangular shape would also work, with the left side presenting a cold surface to the gas, and the right side a hot surface. In fact any kind of right/left geometric/temperature asymmetry would cause a right/left current.

FIG. 29 inverts the configuration shown in FIG. 28 such that the carrier flow is within the temperature generator 29a rather than outside it. The hot and cold sides of the TDGs are thermally shorted by the thermal short 29b to break the thermal equilibrium (equalize actual temperature yet create an effective temperature gradient) and induce particle flow. In the figure the sides are labeled (hot) 29b and (cold) 29c to indicate their temperature in their non-shorted state. Without the thermal short 29d, the TDG 29a would reach thermal equilibrium characterized by zero effective temperature difference, and no heat and no current would flow. On the average, particles would not exchange any heat energy as they collide with the walls of the TDG and particles would lose as much momentum going up the potential energy gradient as they would gather going down the gradient. Therefore no net momentum would be transferred and no current would flow. The thermal shorts 29d break the equilibrium, equalize the actual temperature difference, and induce an effective temperature difference and a current flow.

This phenomenon can be explained in part in terms of the hot probe effect and in part in terms of the radiometer effect. As illustrated in FIG. 1, in accordance with the hot probe effect, a high ZT material subjected to a potential energy gradient can spontaneously develop a temperature difference ΔT_{V=0} (i.e., horizontal axis intercept) in the absence of electrical input.

V=S(ΔT−ΔT_{V=0}) (13)

Without a thermal short, the device is in a state of thermal and electrical equilibrium characterized by a zero effective temperature gradient. No heat and no electrical current flow through it even though there is an actual temperature gradient. If now the device is thermally shorted by thermally connecting its hot side to its cold side, such that the actual temperature difference ΔT=0, an EMF V_{ΔT=0} is generated such that

V_{ΔT=0}=−SΔT_{V=0} (14)

The EMF V_{ΔT=0} results from a modified version of the hot probe effect, in which carrier flow is governed not by the actual temperature difference ΔT but by the effective temperature difference defined as

ΔTᵣₑₗₐₜᵢᵥₑ=ΔT−ΔT_{V=0} (15)

Since ΔT=0 the effective temperature difference is ΔTᵣₑₗₐₜᵢᵥₑΔT_{V=0}. In effect, the thermal short cools the “hot” side of the TDG below equilibrium position by ΔT with respect to the “cold” side. According to this modified hot probe effect, carriers move from the high effective temperature to the cold effective temperature, which paradoxically, is away from the “hot” side (which is cooler than equilibrium) toward the “cold” side (which is hotter than equilibrium). The modified hot probe effect is not sufficient in explaining the flow of the particles. Another aspect of the explanation involves the radiometer effect which requires that the dimensions of the apparatus be approximately of the same order of magnitude as the mean free path.

The design in FIG. 29 depicts a TDG 29a in the shape of a zigzag channel fabricated between two thermally conducting plates. The channel is configured such that all surfaces diagonally facing to the right present a higher potential energy to the carriers than all surfaces diagonally facing to the left. Potential energy can be controlled by the techniques already discussed above using electrodes, electrets, unipolar, Schottky and heterogeneous junctions. The shape of the channel does not have to be a 90 degree zigzag. For example, a smooth S shape would also work with all surfaces approximately diagonally facing to the right presenting to the carriers a higher potential energy than all surfaces diagonally facing to the left. In fact any kind of right/left geometric/temperature asymmetry would cause a right/left current.

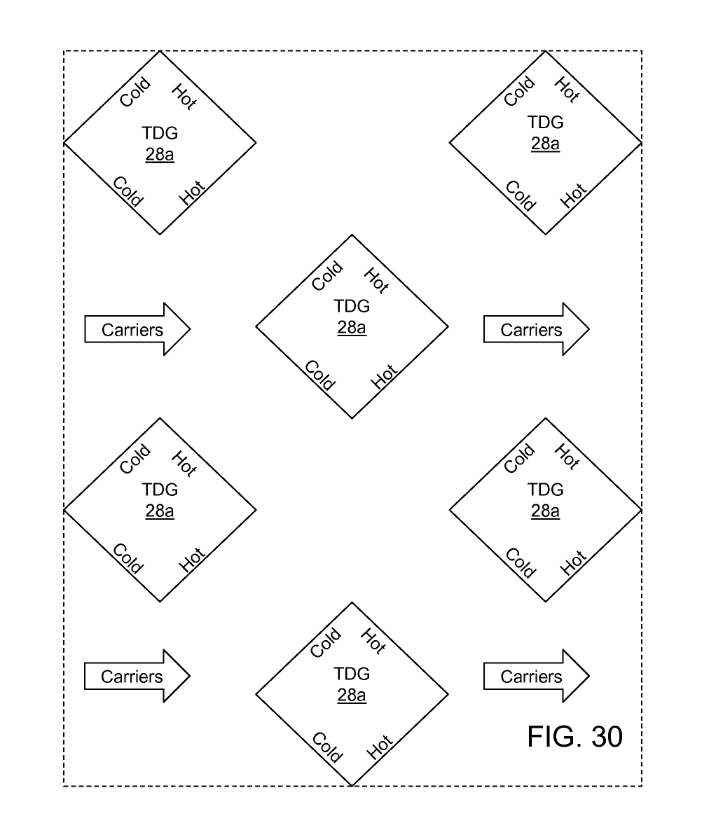

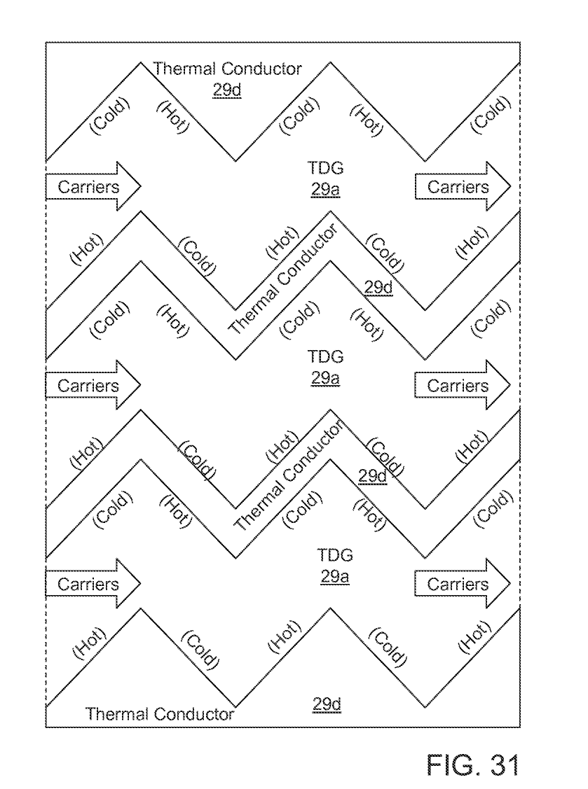

The basic devices of FIGS. 28 and 29 can be concatenated in a large number of ways as illustrated in FIGS. 30 and 31 respectively.

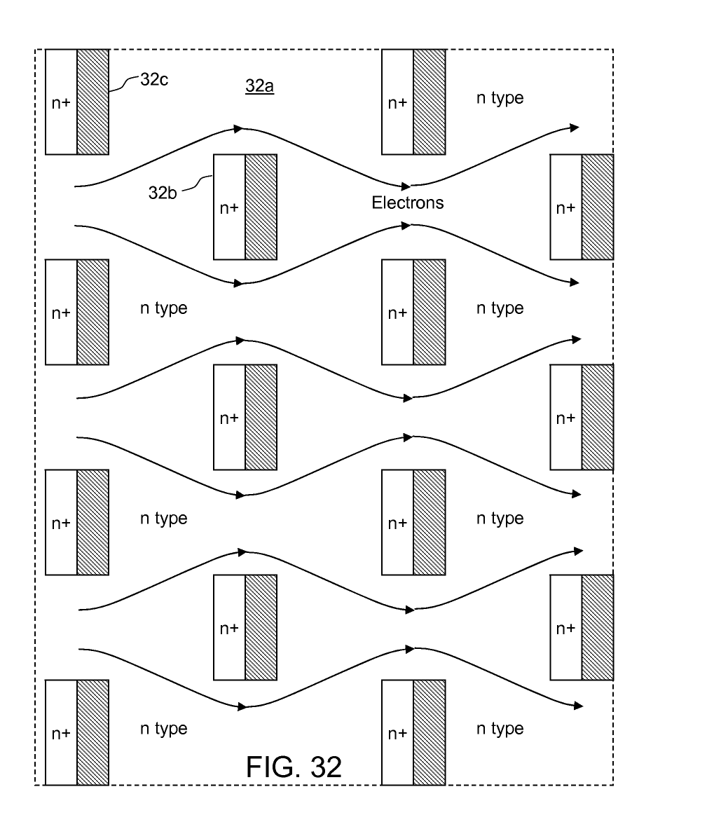

Another possible configuration shown in cross-section in FIG. 32 and inspired from the design in FIG. 30. It is relatively easy to build using standard semiconductor fabrication techniques as it requires depositing layers of electrically insulating, thermally conductive material 32c overlaid with layers of n+ material 32b embedded in an n material matrix 32a. The n+ type layers 32b spontaneously develop a temperature difference with the matrix 32a, but the thermally conductive layers 32c reduce this temperature difference, allowing the n+ layers 32b to have a lower effective temperature than the n type matrix 32a. Therefore according to the modified hot probe effect described above, electrons tend to flow toward the n+ type in the same manner as gas particles flow toward the white vanes of a radiometer. Conversely, the thermally insulating layers 32c have a higher effective temperature than the matrix because heat flows into them from the n+ type layers 32b and therefore electrons move away from them, as air particles move away from the black vanes of a radiometer. The arrows show the path of electrons. Obviously the same kind of architecture can be built with p material, or with materials having different Fermi energies.

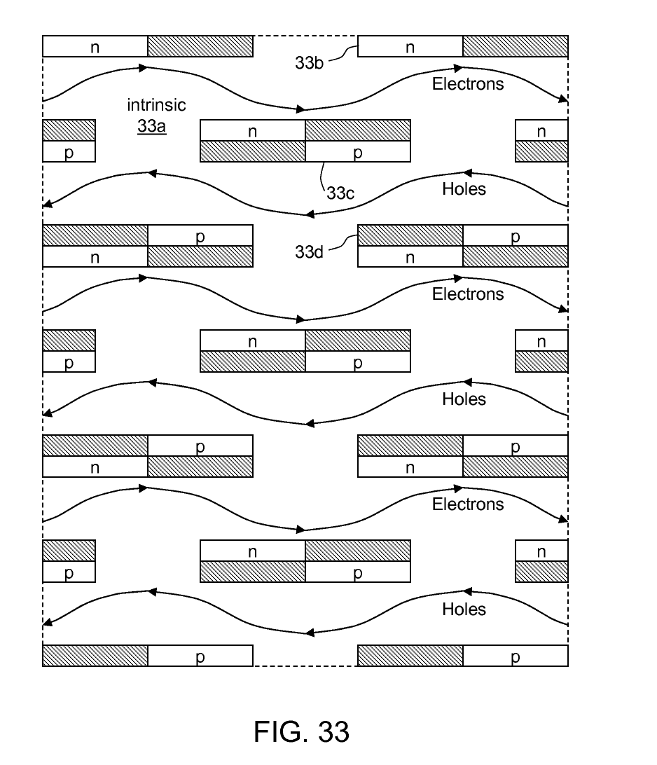

Another version shown in cross-section in FIG. 33 and inspired from FIG. 31 is also relatively easy to fabricate using semiconductor technology as it requires depositing successive layers including electrically insulating, thermally conductive material 33a, n material 33b and n+ material matrix 33c. This version uses the radiometer effect operating in a matrix of intrinsic material 33a embedded with n layers 33b and p layers 33c. The n and p layers are thermally connected to the matrix 33a on one of their sides by thermally conductive, electrically insulating layers 33d. They are in direct contact with the matrix 33a on their other side. The n and p layer spontaneously develop a temperature difference with the matrix at the junction however the thermal connections 33d reduce this difference resulting in the n layers 33b and p layers 33c to have a lower effective temperature than the matrix 33a. According to the modified hot probe effect described above, electrons tend to flow toward the n type layers 33b and holes toward the p type layers 33c. The result is a flow of electrons to the right and of holes to the left, resulting in a net flow of current to the left.

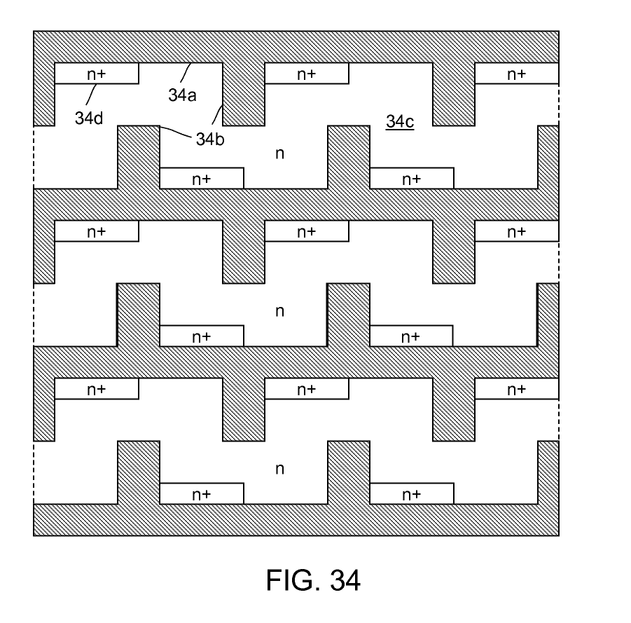

Another version shown in FIG. 34 utilizes baffles 34b configured in the thermally conductive, electrically insulating layer 34a to achieve the required asymmetry to produce a current. The semiconductor matrix 34c comprises n type material. Layers of more highly doped material 34d are inserted between the matrix 34c and the thermally conductive, electrically insulating layer 34a. The potential energy gradient formed between the n material 34c and the n+ material 34d produces a temperature differential which is actually shorted by the layer 34a. The flow of heat phonons in the 34a is accompanied by a flow of electrical carriers in the matrix 34c.

It is evident that there a large number of geometries and configurations exist that can produce a current flow. In addition, TDGs can be used in conjunction with traditional energy sources (such as solar or fuel burning) to augment the performance of Seebeck devices.

### Use of Thermoelectric Materials to Generate Photons

A TDG can produce a temperature difference which drives a Seebeck device. In turn, the Seebeck device produces a current which drives a Light Emitting Diode. This process can be simplified by adapting the radiometer type architectures of FIG. 28-34 to operate as LED's. Essentially two radiometer devices, one of n type and the other of p type, are joined together to form a LED junction. The device needs to be electrically short circuited for the current to flow. Electrons in the n type device are propelled toward the junction by the radiometer effect. Holes in the p type device are also propelled toward the junction by the radiometer effect. Electromagnetic radiation is generated by the annihilation of electrons and holes at the junction.

This particular design requires direct band gap thermoelectric materials such as SbNSr₃ and BiNSr₃ (Ref: 1) M. Bilal, et al, Antiperovskite compounds SbNSr₃ and BiNSr₃Ca5Al2Sb6 and M2Zn5As4(M=K, Rb) available at http://arxiv.org/ftp/arxiv/papers/1306/1306.0648.pdf and 2) Gui Yang, The relation between the electronic structure and thermoelectric transport properties for Zintl compounds M2Zn5As4 (M=K, Rb) available at sciencedirect.com/science/article/pii/S037596011401144X.

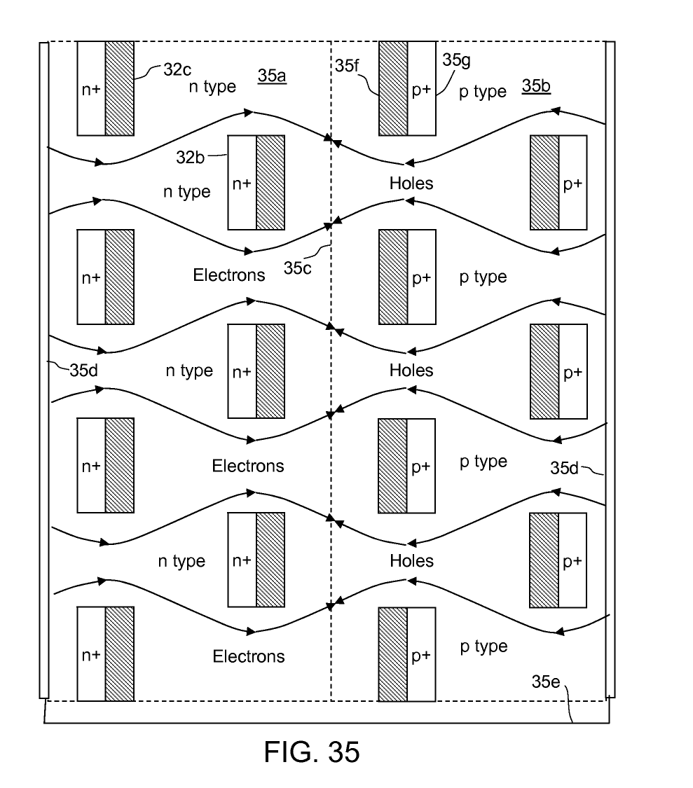

FIG. 35 illustrates this idea. The electrons in the n type material 32a are propelled toward the junction 35c by the TDG 32c. The holes are also propelled toward the junction 35c by the TDGs 35b. The faces of the device are covered with transparent electrodes 35d, for example Indium Tim Oxide, to allow light to exit the device and the electrodes 35d are joined by a connector 35e to allow current to flow according to the radiometer effect. No external voltage source is required. Annihilation of the electrons and holes generates electromagnetic radiation such as light, infrared or microwaves. The electrical circuit is completed by transparent electrodes on either side of the assembly. As heat energy is converted into radiation, heat is replenished by flowing in from the outside.

The device comprises a semiconductor matrix divided into two sections: the first section is occupied by a semiconductor matrix of n type carrying electrons. The second section is occupied by a semiconductor matrix of p type carrying holes. The sections are in contact with each other and forming a junction 35c.

The first section 35a carrying an n type matrix is embedded with n+ type plates, each n+ plate having two faces. The n+ plates are electrically insulated from, and thermally connected to, the matrix on a first n+ face 32c, and the n+ plates are electrically connected and thermally connected to the matrix on a second n+ face 32b, thereby forming a first temperature difference within the matrix, the temperature difference being directed to propel electrons toward the junction;

The second section 35b carrying a p type matrix is embedded with p+ type plates, each p+ plate having two faces. The p+ plates are electrically insulated and thermally connected to the matrix on a first p+ face 35f, and the p+ plates are electrically connected and thermally connected to the matrix on a second p+ face 35g, thereby forming a second temperature difference within the matrix, this temperature difference being directed to propel the holes toward the junction 35c.

The annihilation of electrons and holes at the junction produces an electromagnetic radiation.

### Use of Polar Molecules

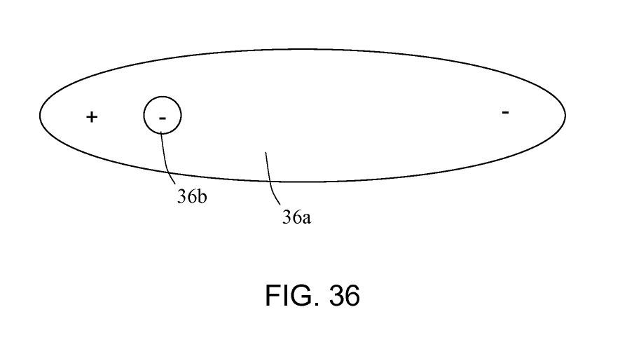

Yet another application shown in FIG. 36 utilizes the temperature difference produced by the potential energy gradient of an electron 36b, induced by the electric field within a single polar molecule 36a. At the lowest potential energy location in the molecule, the electron 36b has the highest kinetic energy and, therefore, raises the energy of the vibrational modes of the molecule at that location. Conversely, at the highest potential energy location, the electron 36b lowers vibrational energy at that location. For better performance, the molecule 36a should have a low internal thermal phonon conductivity in comparison to the electron thermal conductivity. For example, the molecule could consist of two loosely coupled units, each unit having a different intramolecular affinity for electrons, thereby forming a dipole with a low thermal conductivity.

### Materials

Thermoelectric materials include but are not restricted to
1) Bismuth chalcogenides for example such as Bi₂Te₃ and Bi₂Se₃ sometimes doped with Sb or Sn. A typical doping ratio is for an n material (0.98Bi₃0.02Sb)₂(0.9Te,0.1Se)₃, and for a p material (0.25Bi₃0.75Sb)₂(0.95Te,0.05Se)₃.
2) Lead telluride
3) Inorganic clathrates
4) Magnesium group IV compounds of the form Mg₂B^{IV} (B^{IV}═Si, Ge, Sn)
5) Silicides
6) Skutterudite for example of the form (Co,Ni, Fe)(P, Sb, As)₃
7) Oxide thermoelectrics (homologous oxide compounds with layered superlattice structure gives such as those of the form (SrTiO3)ₙ(SrO)ₘ
8) Half Heusler alloys
9) Electrically conducting organic materials
10) Silicon-germanium
11) Sodium-cobaltate
12) Tin selenide

Forming a Schottky junction requires joining a metal to a thermoelectric material such that the selected metal and thermoelectric material have a different work function Metals include (using their symbols) Al, Si, P, Ti, V, Cr, Mn, Fe, Co, Ni, Cu, Zn, Ga, Ge, As, Se, Y, Ze, Nb, Mo, Tc, Ru, Rh, Pd, Ag, Cd, In, Sn, Sb, Te, LaHf, Ta, W, Re, Os, Ir, Pt, Au, Tl, Pb, Bi, Ce, Pr, Nd, Pm, Eu, Gd, Tb, Dy, Ho, Er, Tm, Yb, Lu, Th, and U.

### Fabrication Methods

Methods of joining a metal to the thermoelectric material or for joining two thermoelectric materials include but are not restricted to hot pressing, sputtering, physical vapor deposition, chemical vapor deposition, electrodeless plating, electroplating, atomic layer deposition, molecular beam epitaxy, metalorganic vapor deposition, spin coating, ion plating, vacuum deposition, spraying and electron beam evaporation.

Method of joining two thermoeectric, material in crystalline form include epitaxy, (heteroepitaxy, heterotopotaxi, pendeo-epitaxy, These process can be performed in vapor phase, liquid phase or solid phase as appropriate. When the deposited material comprises different kinds of atoms, molecular-beam epitaxy can be used.

The deposited layer can be doped by adding impurities to the source gas or liquid. Doping can also be implemented by ultrafast laser pulses.

### Applications

Applications of this technology include refrigerators, heaters and heat pumps that can operate without requiring an electrical power input. Depending on how the layers of thermoelectric material are arranged, they could operate as heaters or as coolers. They would simply transfer heat energy from one place to another without requiring any energy input. When this technology is associated with thermal to electrical generators (such as thermoelectric devices) it can be used to convert ambient heat into electric energy. Electrical generators using this technology draw power directly from their environments leaving cold as a by-product.

Applications also include controllable and reversible heaters and coolers. A voltage applied between two capacitively coupled plates can be used to control the electrical field going through a thermoelectric material placed between (but insulated from) the plates. Since the electrical field is required for the adiabatic effect in the thermoelectric material, the voltage can be used to control the magnitude and the direction of the thermo-motive force. A heater can become a refrigerator and vice versa.

Yet other applications include power supplies for semiconductor chips and semiconductor modules. These power supplies can be fabricated as integral subcomponents of these chips or modules. Since their by-product is cold, these power supplies can also serve as coolers for the chips or modules. In essence, the heat energy generated by semiconductor chips is captured and reused by the chips.

Other applications include electricity generation, for example:
Forever Batteries—output is electrical power, by-product is cold
Wireless Forever Lights—with embedded LED, by-product is cold
Self-powered Semiconductor chips—recycle their own energy
Self powered electrical cars with infinite range, no exhaust, no recharge
Self-powered houses independent of the electrical grid.
Less need or no need for power transmission lines.

Food Packaging, Storage and Preparation are also possible applications of this technology. Applications include:
Food containers with switchable heat pumps to keep food frozen during transport and storage. Before consumption, the heat pump is switched to a heater mode.
Refrigerators can operate without power input—by-product is heat.

While the above description contains many specificities, the reader should not construe these as limitations on the scope of the invention, but merely as exemplifications of preferred embodiments thereof. Those skilled in the art will envision many other possible variations within its scope. Accordingly, the reader is requested to determine the scope of the invention by the appended claims and their legal equivalents, and not by the examples which have been given.

### REFERENCES AND NOTES

1. Maxwell-Boltzmann Distribution, Wikipedia
2. Levy, G. “Thermoelectric Effects under Adiabatic Conditions” Entropy 2013, 15(11), 4700-4715 available at http://www.mdpi.com/1099-4300/15/11/4700#stats.
3. Levy, G. “Anomalous Temperature Gradient in Non-Maxwellian Gases,” ResearchGate, available on line at http://www.researchgate.net/publication/272621625_Anomalous_Temperature_Gradient_in_Non-Maxwellian_Gases
4. van Zeghbroeck, Bart, “Principles of Electronic Devices” on line.
5. van Zeghbroeck, Bart; “Carrier density and the Fermi energy,” on line
6. Iwanaga, S et al. A high temperature apparatus for measurement of the Seebeck coefficient. Rev. Sci. Instrum. 2011, 82, 063905-1-063905-6.
7. Snyder, J. Material Science, Caltech, Private communication on 20 Jan. 2012.
8. Snyder, J., Material Science, Caltech, Private communication on 9 Apr. 2012.
9. Fermi-Dirac Statistics; Wikipedia.
10. Complete Fermi-Dirac Integrals; Wikipedia.
11. Bilal, M, et al, Antiperovskite compounds SbNSr₃ and BiNSr₃ and Ca5Al2Sb6 and M2Zn5As4(M=K, Rb) http://arxiv.org/ftp/arxiv/papers/1306/1306.0648.pdf
12. Gui Yang, The relation between the electronic structure and thermoelectric transport properties for Zintl compounds M2Zn5As4 (M=K, Rb) http://www.sciencedirect.com/science/article/pii/S037596011401144X
13. Reynolds, Osborne one the web at Osborne Reynolds, Collected Papers on Mechanical and Physical Subjects, in three volumes, published circa 1903, article 23, pages 170, 182,

I claim:

1. An energy generator comprising:
a) non-Maxwellian particles in a gas phase, said particles being restricted in their movement to a volume, and said particles having a temperature distribution across said volume; and
b) a potential energy gradient inducing said particles to acquire a non-uniform temperature distribution across said volume, resulting in a temperature difference between a cold region and a hot region in said volume;

2. The energy generator of claim 1 wherein said volume is shaped to maximize said potential gradient.

3. The energy generator of claim 1 wherein said particles move within a material filling said volume, said temperature difference being maximized by selecting a material with a high ZT coefficient.

4. The energy generator of claim 1 wherein said particles are Fermions.

5. The energy generator of claim 1 wherein said particles are electrons.

6. The energy generator of claim 1 wherein said particles are holes.

7. The energy generator of claim 1 wherein said particles are Bosons.

8. The energy generator of claim 1 wherein said potential energy gradient is produced by electrodes external to said volume.

9. The energy generator of claim 1 wherein said potential energy gradient is produced by electrets external to said volume.

10. The energy generator of claim 1 wherein said potential energy gradient is produced by a semiconductor junction.

11. The energy generator of claim 1 wherein said potential energy gradient is produced by a unipolar semiconductor junction.

12. The energy generator of claim 1 wherein said potential energy gradient is produced by a Schottky junction.

13. The energy generator of claim 1 wherein said potential energy gradient is produced by a hetero-junction.

14. The energy generator of claim 1 configured also as a heater or a cooler, also comprising a cold sink or a heat sink.

15. An energy generator comprising a stack, each stack element comprising:
a) non-Maxwellian particles in a gas phase, said particles being restricted in their movement to a volume, and said particles having a temperature distribution across said volume; and
b) a potential energy gradient inducing said particles to acquire a non-uniform temperature distribution across said volume, resulting in a temperature difference between a cold region and a hot region in said volume;

16. The energy generator of claim 1 also comprising a Seebeck device connected between said hot region and said cold region, said Seebeck device producing electricity.

17. The energy generator of claim 1 configured to utilize a fixed-vane Crookes radiometer effect, wherein:
a) said volume is occupied by a semiconductor matrix of n type or p type
b) said particles being electrical carriers moving in said semiconductor matrix;
c) said n type or p type matrix respectively embedded with n+ type plates or p+ type plates, said plates being electrically insulated and thermally connected to said matrix on a first side, and said plates being in electrical contact with said matrix on a second side, thereby forming said temperature difference within said matrix, said temperature difference being directed to propel said electrical carriers thereby generating a current.

18. The energy generator of claim 1 configured to utilize an electrical analog of a fixed-vane Crookes radiometer, wherein said volume is divided into two sections:
a) first said section being occupied by a semiconductor matrix of n type carrying electrons;
b) second said section being occupied by a semiconductor matrix of p type carrying holes;
c) said sections being in contact with each other and forming a junction;
d) said first n type section being embedded with n+ type plates, each said n+ plate having two faces, said n+ plates being electrically insulated from, and thermally connected to, said matrix on a first n+ face, and said n+ plates being electrically connected and thermally connected to said matrix on a second n+ face, thereby forming a first said temperature difference within said matrix, said first temperature difference being directed to propel said electrons toward said junction;
e) said second p type section being embedded with p+ type plates, each said p+ plate having two faces, said p+ plates being electrically insulated from, and thermally connected to, said matrix on a first p+ face, and said p+ plates being electrically connected and thermally connected to said matrix on a second p+ face, thereby forming a second said temperature difference within said matrix, said first temperature difference being directed to propel said holes toward said junction;
f) annihilation of said electrons and said holes at said junction producing electromagnetic radiation.

19. The energy generator of claim 1 wherein said volume comprises a quantum well material.

20. The energy generator of claim 1 wherein
a) said particles are at least one electron or hole and confined to a polar molecule, said particle in a conduction band of said polar molecule, said polar molecule having two polar ends;
b) said potential energy gradient is caused by an electric field generated by said polar molecule; and
c) said cold region is one of said polar ends and repels said electron or hole, and said hot region is one of said polar ends and attracts said electron or hole.
